(19) United States
(12) Patent Application Publication
(10) Pub. No.: US 2023/0221637 A1
(43) Pub. Date: Jul. 13, 2023

(54) Holographic Recording Materials and Methods of Making Same

(71) Applicant: The Regents of the University of Colorado, a body corporate, Denver, CO (US)

(72) Inventors: Christopher N. Bowman, Boulder, CO (US); Sudheendran Mavila, Boulder, CO (US); Jasmine Sinha, Boulder, CO (US); Yunfeng HU, Boulder, CO (US); Maciej Podgorski, Boulder, CO (US)

(21) Appl. No.: 18/009,618

(22) PCT Filed: Jun. 9, 2021
(86) PCT No.: PCT/US2021/036662

§ 371 Date: Dec. 9, 2022

Related U.S. Application Data
(60) Provisional application No. 63/037,296, filed on Jun. 10, 2020.

(51) Int. Cl. G03F 7/00; C08G 75/045; C08G 18/73; C08G 18/48; C08G 18/67; C08F 290/06; G03H 1/02

(52) U.S. Cl. CPC G03F 7/001; C08G 75/045; C08G 18/73; C08G 18/4887; C08G 18/675; C08F 290/061; G03H 1/02; G03H 2260/12; G03H 2001/0264

(57) ABSTRACT

Provided herein are compositions suitable for recording holograms containing thiol and/or thioether functionality, and optionally including additional allyl and/or propargyl functional groups. These monomers can be used to synthesize holographic poly-mers having high Lin values. Also provided herein are methods of making holographic polymers and methods recording holograms using these polymers.

### CROSS-REFERENCE TO RELATED APPLICATION

This application claims priority to U.S. Provisional Patent Application Ser. No. 63/037,296 entitled “HOLOGRAPHIC RECORDING MATERIALS AND METHODS OF MAKING SAME,” filed Jun. 10, 2020, the disclosure of which is incorporated herein by reference in its entirety.

### BACKGROUND

Holographic photopolymers are an appealing and often necessary material platform for applications including heads-up displays, data storage, and diffractive optical elements, due to these polymers' processing ease and capacity for single-step recording. For all these applications, a crucial performance specification directly correlated to the device quality and performance is the achievable index modulation (Δn). Efforts to improve index modulation have focused on enhancing the index contrast between the writing monomer and the matrix, while maintaining high monomer solubility that enables high writing monomer loadings in non-phase separated polymers.

There is a need in the art for novel holographic recording materials and methods of making the same. The present invention addresses this need.

### BRIEF SUMMARY OF THE INVENTION

In various embodiments, a composition is provided. In certain embodiments, the composition includes:
at least one polymer;
a polymer binder comprising a plurality of allyl groups; and
at least one monomer of formula (I):

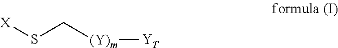

and at least one monomer of formula (II):

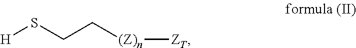

wherein:
each occurrence of X is independently H or optionally substituted C₆₋₁₄ aryl;
each Y is independently —S—, —CH₂—, —CH₂CH₂—, —CH(CH₃)CH₂—, —CH₂CH(CH₃)—, —CH(SH)—, —CH[O—CH₂—CH═CH₂]—, or —CH[O—CH₂—C≡CH]—;
each Y_{T} is independently H, —SH, —CH═CH₂, —C≡CH, or optionally substituted C₆₋₁₄ aryl;
each Z is independently —S—, —CH₂, —CH₂CH₂—, —CH(CH₃)CH₂—, —CH₂CH(CH₃)—, or —CH(SH)—;
each Z_{T} is independently H, —SH or —CH₂SH;
m is an integer ranging from 0 to 100; and
n is an integer ranging from 0 to 100.

Advantageously, in various embodiments, the composition can be used to form a holographic material.

### BRIEF DESCRIPTION OF THE FIGURES

The drawings illustrate generally, by way of example, but not by way of limitation, various embodiments of the present application.

FIGS. 1A-1D show schematic illustrations of the preparation of holographic film and hologram formation. FIG. 1A shows formulation of writing monomers and linear binder with pedant allyl side chains. FIG. 1B shows hologram formation and flood curing. FIG. 1C shows formulation of alcohol-isocyanate linear binder. FIG. 1D is a photo of typical holograms taken under illumination of a PC monitor in right front. The formulation used contains 43 w % thiol-ene writing monomers and 30 mol % allyl in binder.

FIGS. 2A-2D show hologram performance in terms of dynamic range (Δn). FIG. 2A shows an angular playback spectrum of a representative hologram, showing good agreement with a fit to the Kogelnik equation. (Holographic pitch is A=1 m; the formulation has 30 mol % allyl and 43 w % thiol-ene). FIG. 2B shows dynamic ranges of holograms of various loading of thiol-ene writing monomer at pitch A=0.5 m. FIG. 2C shows the effect of grating period on dynamic ranges of various formulation. FIG. 2D shows an image of atomic force microscopy (AFM) of a sample with 20 w % thiol-ene writing monomers and 30 mol % allyl in polymer binder.

FIG. 3 shows spectra of a recorded reflection hologram (30 mol % allyl in polymer binder, 43 w % thiol-ene writing monomers).

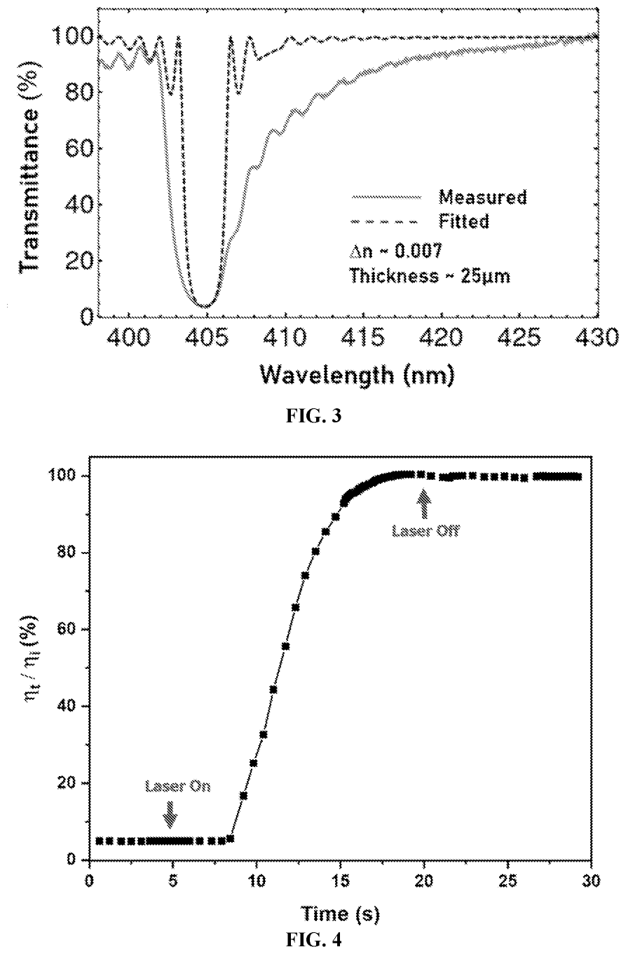

FIG. 4 shows a graph of diffraction efficiency (DE) vs. development over time (43 w % thiol-ene monomers and 30 mol % allyl).

FIG. 5 shows a profile characterization of the same hologram recorded film in FIG. 4.

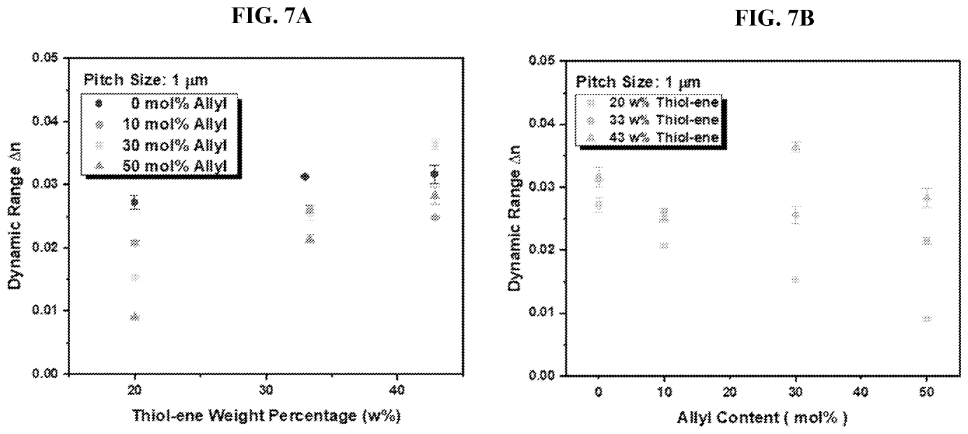

FIG. 6 shows a profile characterization of a thick hologram film for recording reflection holograms.

FIGS. 7A-7B show dynamic ranges of transmission holograms recorded with a pitch size of 1 μm. FIG. 7A shows dynamic ranges of holograms of various loading of thiol-ene writing monomer. FIG. 7B shows the effect of allyl content on dynamic ranges of various formulations.

FIGS. 8A-8B illustrate the effect of grating period on dynamic ranges of various formulation (where Λ is the spatial period). FIG. 8A shows the effect with a 20 w % thiol-ene writing monomer loading. FIG. 8B shows the effect with a 33 w % thiol-ene writing monomer loading.

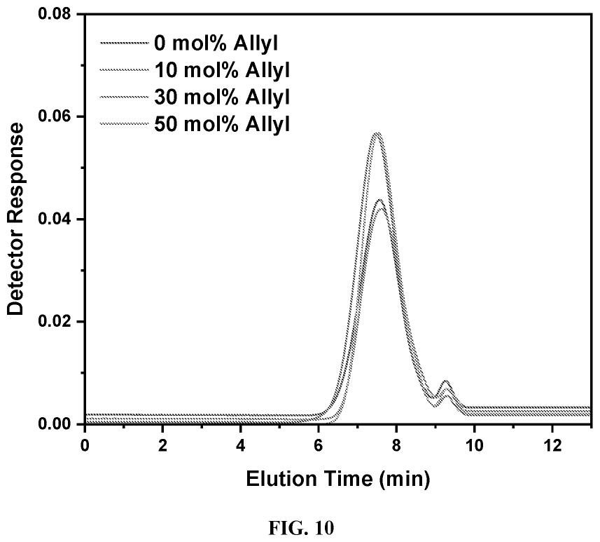

FIGS. 9A-9B illustrate the tunability of dynamic range of thiol-ene based holograms at either 0.5 μm (FIG. 9A) or 1 μm (FIG. 9B) pitch size.

FIG. 10 shows GPC (gel permeation chromatography) curves of linear matrices with various amounts of allyl content.

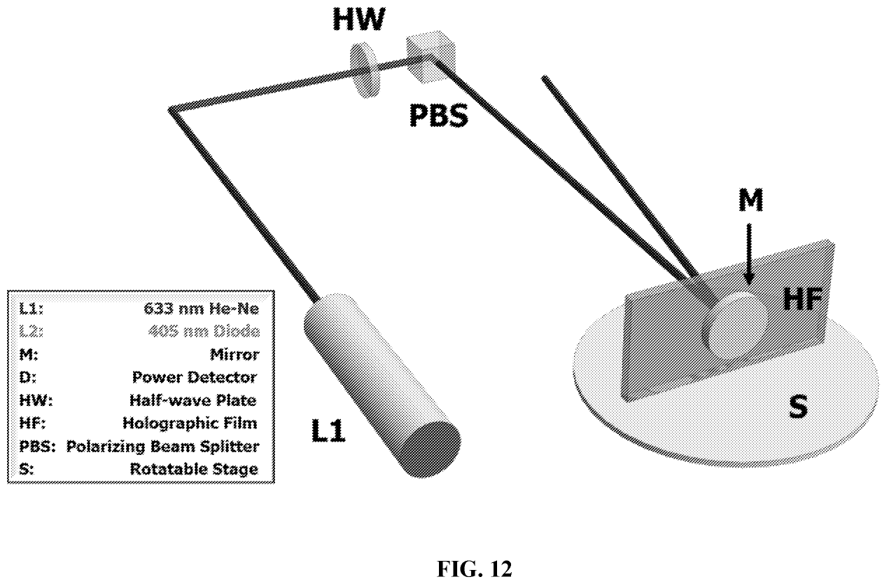

FIG. 11 illustrates an optical layout for transmission hologram exposure and playback. Component labels: L1, 633 nm He—Ne laser; L2, 405 nm diode laser; M, mirror; D, power detector; HW, half-wave plate; HF, holographic film; PBS, polarizing beam splitter; S, rotatable stage.

FIG. 12 shows an optical layout for reflection hologram exposure. Component labels: L1, 633 nm He—Ne laser; M, mirror; D, power detector; HW, half-wave plate; HF, holographic film; PBS, polarizing beam splitter; S, rotatable stage.

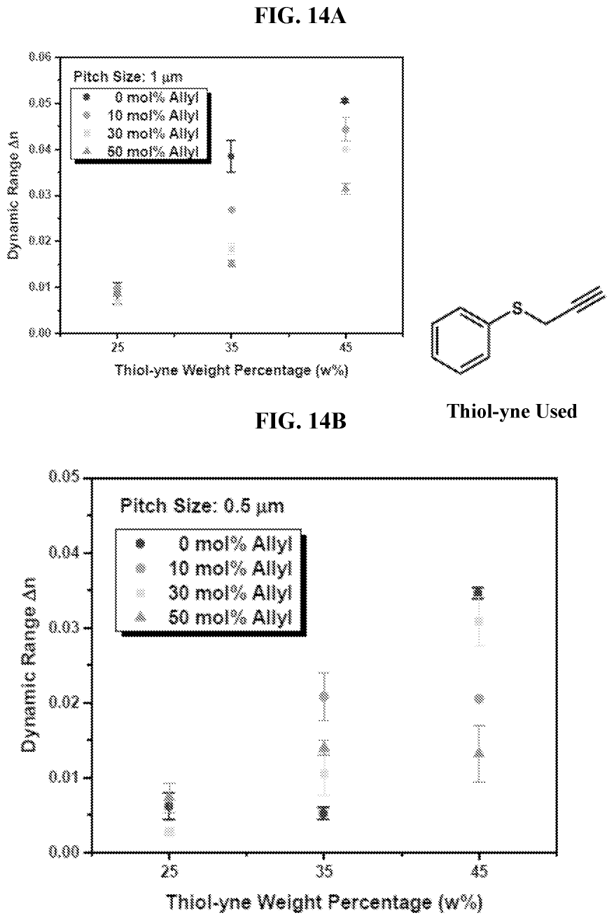

FIGS. 13A-13B show AFM images of holograms. FIG. 13A has allyl content of 30 mol % and 30 w % thiol-ene writing monomers. FIG. 13B has 43 w % thiol-ene writing monomers and allyl content of 30 mol %.

FIGS. 14A-14B show dynamic range as a function of weight % of thiol-yne photopolymers with 1 m pitch (FIG. 14A) or 0.5 m pitch (FIG. 14B). The alkyne used is shown in the figure, and the thiol is 1,3-bis(2-mercaptoethylthio)-2-mercaptopropane.

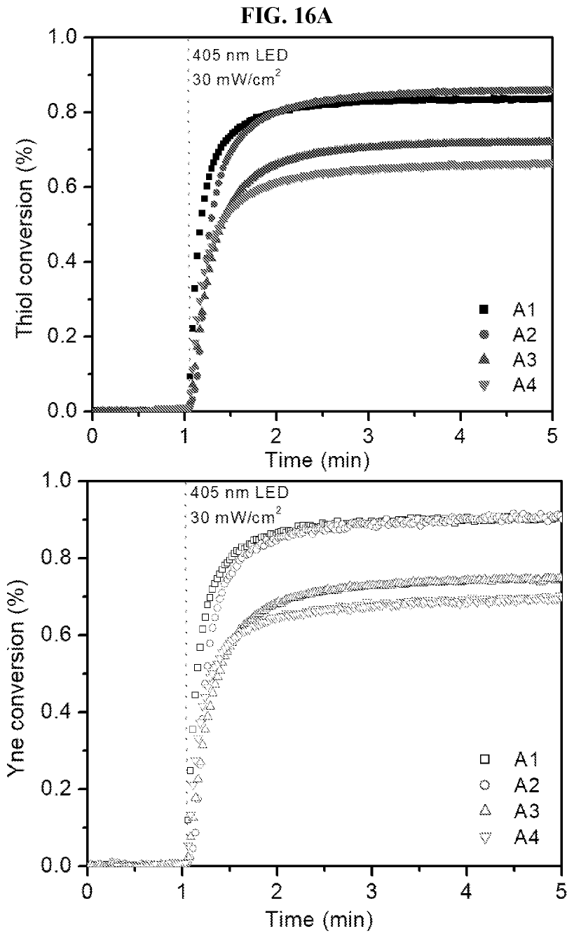

FIGS. 15A-15B show properties of thiol-yne photopolymers. FIG. 15A shows dynamic range as a function of writing monomer weight % using thiol-yne photopolymers with a 0.5 m pitch. The thioalkyne used is shown in the figure, and the thiol is 1,3-bis(2-mercaptoethylthio)-2-mercaptopropane. FIG. 15B shows conversion as a function of time during the photopolymerization of 1,3-bis(2-mercaptoethylthio)-2-mercaptopropane and the alkyne shown.

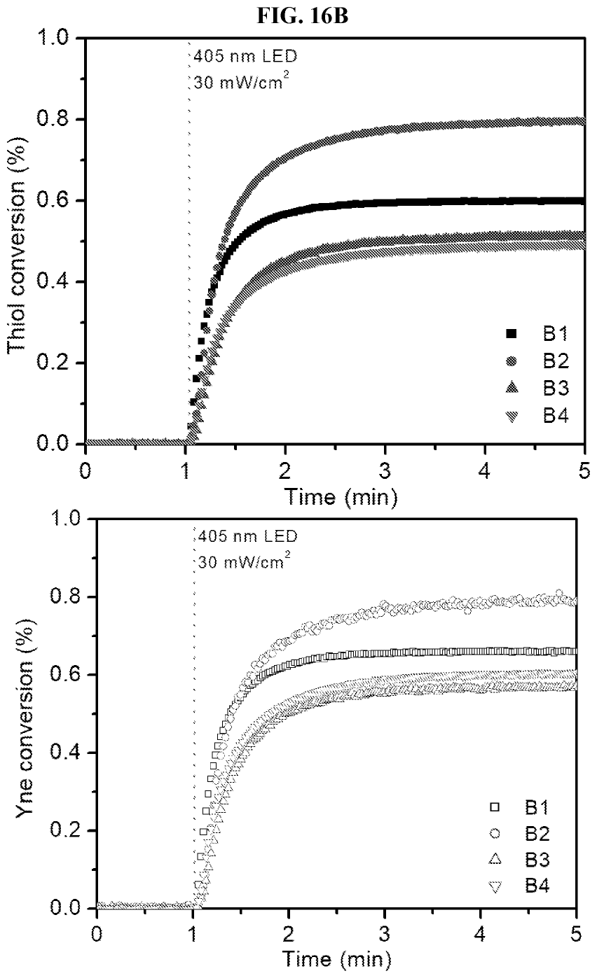

FIGS. 16A-16C show FTIR conversion vs. time plots for formulation A1 (FIG. 16A), B1 (FIG. 16B) and C1 (FIG. 16C). The mixture consists of initial stoichiometric ratios of 2:1 thiol to alkyne functional group concentrations. Each sample was stabilized in the dark for 1 min and then irradiated with 30 mW/cm² 405 nm wavelength light at ambient temperature.

FIGS. 17A-17C show thermochemical properties of thiol-yne photopolymers. Storage modulus and tan δ plots versus temperature for each thiol-yne photopolymer film characteristic of step-growth networks. DMA experiments were performed on the samples after post curing overnight at 70° C.

FIG. 18 is a plot of refractive index as a function of thiol conversion observed for formulation B2 upon irradiation with 405 nm light, 30 mW/cm².

FIGS. 19A-19B show properties of holograms recorded in a thiol-yne photopolymer, according to some embodiments. FIG. 19A shows an angular playback spectrum of a hologram recorded with 2d as writing monomer showing good fit to the coupled wave theory.

FIG. 19B is a table summarizing the dynamic ranges and haze measured for holograms with various alkyne writing monomers.

FIG. 20 shows a two-dimensional, micrometer-scale refractive index structures recorded on a two stage poly(urethane-thiourethane) (Stage 1)/thiol-yne resin B2 (stage 2) matrix via an irradiation through a photomask.

FIGS. 21A-21C are real-time FTIR plots showing the formation and conversion of vinyl sulfide for the formulations A(1-4) (FIG. 21A), B(1-4) (FIG. 21B) and C(1-4) (FIG. 21C) upon irradiation with 405 nm light, 30 mW/cm². The mixture consists of an initial stoichiometric ratio of 2:1 thiol to vinyl functional group concentration. Each sample was stabilized in the dark for 1 min and then irradiated.

FIG. 22 shows the structure of model thiol-yne monomers used to determine the reactivity of 1° and 2° thiols towards monoalkyne and their resin formulation with 2:1 molar ratio of thiol and alkyne reactive groups.

FIGS. 23A-23B show real-time FTIR data for formulations M1 and M2 showing the reactivity of 1° and 2° thiols towards monoalkyne as a function of thiol conversion (FIG. 23A) and yne/vinyl conversion (FIG. 23B). The mixture consists of an initial stoichiometric ratio of 2:1 thiol to vinyl functional group concentration. Each sample was stabilized in the dark for 1 min and then irradiated.

### DETAILED DESCRIPTION OF THE INVENTION

In one aspect, described herein is a high-performance holographic recording media based on a combination of photoinitiated thiol-ene click chemistry and functional, linear polymers used as binders that resulted in a holographic material with significantly improved and stable mean index contrast (Δn).

Reference will now be made in detail to certain embodiments of the disclosed subject matter, examples of which are illustrated in part in the accompanying drawings. While the disclosed subject matter will be described in conjunction with the enumerated claims, it will be understood that the exemplified subject matter is not intended to limit the claims to the disclosed subject matter.

Throughout this document, values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “about 0.1% to about 5%” or “about 0.1% to 5%” should be interpreted to include not just about 0.1% to about 5%, but also the individual values (e.g., 1%, 2%, 3%, and 4%) and the sub-ranges (e.g., 0.1% to 0.5%, 1.1% to 2.2%, 3.3% to 4.4%) within the indicated range. The statement “about X to Y” has the same meaning as “about X to about Y,” unless indicated otherwise. Likewise, the statement “about X, Y, or about Z” has the same meaning as “about X, about Y, or about Z,” unless indicated otherwise.

In this document, the terms “a,” “an,” or “the” are used to include one or more than one unless the context clearly dictates otherwise. The term “or” is used to refer to a nonexclusive “or” unless otherwise indicated. The statement “at least one of A and B” or “at least one of A or B” has the same meaning as “A, B, or A and B.” In addition, it is to be understood that the phraseology or terminology employed herein, and not otherwise defined, is for the purpose of description only and not of limitation. Any use of section headings is intended to aid reading of the document and is not to be interpreted as limiting; information that is relevant to a section heading may occur within or outside of that particular section. All publications, patents, and patent documents referred to in this document are incorporated by reference herein in their entirety, as though individually incorporated by reference.

In the methods described herein, the acts can be carried out in any order, except when a temporal or operational sequence is explicitly recited. Furthermore, specified acts can be carried out concurrently unless explicit claim language recites that they be carried out separately. For example, a claimed act of doing X and a claimed act of doing Y can be conducted simultaneously within a single operation, and the resulting process will fall within the literal scope of the claimed process.

### Definitions

The term “about” as used herein can allow for a degree of variability in a value or range, for example, within 10%, within 5%, or within 1% of a stated value or of a stated limit of a range, and includes the exact stated value or range.

The term “substantially” as used herein refers to a majority of, or mostly, as in at least about 50%, 60%, 70%, 80%, 90%, 95%, 96%, 97%, 98%, 99%, 99.5%, 99.9%, 99.99%, or at least about 99.999% or more, or 100%. The term “substantially free of” as used herein can mean having none or having a trivial amount of, such that the amount of material present does not affect the material properties of the composition including the material, such that the composition is about 0 wt % to about 5 wt % of the material, or about 0 wt % to about 1 wt %, or about 5 wt % or less, or less than, equal to, or greater than about 4.5 wt %, 4, 3.5, 3, 2.5, 2, 1.5, 1, 0.9, 0.8, 0.7, 0.6, 0.5, 0.4, 0.3, 0.2, 0.1, 0.01, or about 0.001 wt % or less. The term “substantially free of” can mean having a trivial amount of, such that a composition is about 0 wt % to about 5 wt % of the material, or about 0 wt % to about 1 wt %, or about 5 wt % or less, or less than, equal to, or greater than about 4.5 wt %, 4, 3.5, 3, 2.5, 2, 1.5, 1, 0.9, 0.8, 0.7, 0.6, 0.5, 0.4, 0.3, 0.2, 0.1, 0.01, or about 0.001 wt % or less, or about 0 wt %.

The term “organic group” as used herein refers to any carbon-containing functional group. Examples can include an oxygen-containing group such as an alkoxy group, aryloxy group, aralkyloxy group, oxo(carbonyl) group; a carboxyl group including a carboxylic acid, carboxylate, and a carboxylate ester; a sulfur-containing group such as an alkyl and aryl sulfide group; and other heteroatom-containing groups. Non-limiting examples of organic groups include OR, OOR, OC(O)N(R)₂, CN, CF₃, OCF₃, R, C(O), methylenedioxy, ethylenedioxy, N(R)₂, SR, SOR, SO₂R, SO₂N(R)₂, SO₃R, C(O)R, C(O)C(O)R, C(O)CH₂C(O)R, C(S)R, C(O)OR, OC(O)R, C(O)N(R)₂, OC(O)N(R)₂, C(S)N(R)₂, (CH₂)₀₋₂N(R)C(O)R, (CH₂)₀₋₂N(R)N(R)₂, N(R)N(R)C(O)R, N(R)N(R)C(O)OR, N(R)N(R)CON(R)₂, N(R)SO₂R, N(R)SO₂N(R)₂, N(R)C(O)OR, N(R)C(O)R, N(R)C(S)R, N(R)C(O)N(R)₂, N(R)C(S)N(R)₂, N(COR)COR, N(OR)R, C(═NH)N(R)₂, C(O)N(OR)R, C(═NOR)R, and substituted or unsubstituted (C₁-C₁₀₀)hydrocarbyl, wherein R can be hydrogen (in examples that include other carbon atoms) or a carbon-based moiety, and wherein the carbon-based moiety can be substituted or unsubstituted.

The term “substituted” as used herein in conjunction with a molecule or an organic group as defined herein refers to the state in which one or more hydrogen atoms contained therein are replaced by one or more non-hydrogen atoms. The term “functional group” or “substituent” as used herein refers to a group that can be or is substituted onto a molecule or onto an organic group. Examples of substituents or functional groups include, but are not limited to, a halogen (e.g., F, Cl, Br, and I); an oxygen atom in groups such as hydroxy groups, alkoxy groups, aryloxy groups, aralkyloxy groups, oxo(carbonyl) groups, carboxyl groups including carboxylic acids, carboxylates, and carboxylate esters; a sulfur atom in groups such as thiol groups, alkyl and aryl sulfide groups, sulfoxide groups, sulfone groups, sulfonyl groups, and sulfonamide groups; a nitrogen atom in groups such as amines, hydroxyamines, nitriles, nitro groups, N-oxides, hydrazides, azides, and enamines; and other heteroatoms in various other groups. Non-limiting examples of substituents that can be bonded to a substituted carbon (or other) atom include F, Cl, Br, I, OR, OC(O)N(R)₂, CN, NO, NO₂, ONO₂, azido, CF₃, OCF₃, R, O (oxo), S (thiono), C(O), S(O), methylenedioxy, ethylenedioxy, N(R)₂, SR, SOR, SO₂R, SO₂N(R)₂, SO₃R, C(O)R, C(O)C(O)R, C(O)CH₂C(O)R, C(S)R, C(O)OR, OC(O)R, C(O)N(R)₂, OC(O)N(R)₂, C(S)N(R)₂, (CH₂)₀₋₂N(R)C(O)R, (CH₂)₀₋₂N(R)N(R)₂, N(R)N(R)C(O)R, N(R)N(R)C(O)OR, N(R)N(R)CON(R)₂, N(R)SO₂R, N(R)SO₂N(R)₂, N(R)C(O)OR, N(R)C(O)R, N(R)C(S)R, N(R)C(O)N(R)₂, N(R)C(S)N(R)₂, N(COR)COR, N(OR)R, C(═NH)N(R)₂, C(O)N(OR)R, and C(═NOR)R, wherein R can be hydrogen or a carbon-based moiety; for example, R can be hydrogen, (C₁-C₁₀₀)hydrocarbyl, alkyl, acyl, cycloalkyl, aryl, aralkyl, heterocyclyl, heteroaryl, or heteroarylalkyl; or wherein two R groups bonded to a nitrogen atom or to adjacent nitrogen atoms can together with the nitrogen atom or atoms form a heterocyclyl.

The term “alkyl” as used herein refers to straight chain and branched alkyl groups and cycloalkyl groups having from 1 to 40 carbon atoms, 1 to about 20 carbon atoms, 1 to 12 carbons or, in some embodiments, from 1 to 8 carbon atoms. Examples of straight chain alkyl groups include those with from 1 to 8 carbon atoms such as methyl, ethyl, n-propyl, n-butyl, n-pentyl, n-hexyl, n-heptyl, and n-octyl groups. Examples of branched alkyl groups include, but are not limited to, isopropyl, iso-butyl, sec-butyl, t-butyl, neopentyl, isopentyl, and 2,2-dimethylpropyl groups. As used herein, the term “alkyl” encompasses n-alkyl, isoalkyl, and anteisoalkyl groups as well as other branched chain forms of alkyl. Representative substituted alkyl groups can be substituted one or more times with any of the groups listed herein, for example, amino, hydroxy, cyano, carboxy, nitro, thio, alkoxy, and halogen groups.

The term “alkenyl” as used herein refers to straight and branched chain and cyclic alkyl groups as defined herein, except that at least one double bond exists between two carbon atoms. Thus, alkenyl groups have from 2 to 40 carbon atoms, or 2 to about 20 carbon atoms, or 2 to 12 carbon atoms or, in some embodiments, from 2 to 8 carbon atoms. Examples include, but are not limited to vinyl, —CH═C═CCH₂, —CH═CH(CH₃), —CH═C(CH₃)₂, —C(CH₃)═CH₂, —C(CH₃)═CH(CH₃), —C(CH₂CH₃)═CH₂, cyclohexenyl, cyclopentenyl, cyclohexadienyl, butadienyl, pentadienyl, and hexadienyl among others.

The term “alkynyl” as used herein refers to straight and branched chain alkyl groups, except that at least one triple bond exists between two carbon atoms. Thus, alkynyl groups have from 2 to 40 carbon atoms, 2 to about 20 carbon atoms, or from 2 to 12 carbons or, in some embodiments, from 2 to 8 carbon atoms. Examples include, but are not limited to —C≡CH, —C≡C(CH₃), —C≡C(CH₂CH₃), —CH₂C≡CH, —CH₂C≡C(CH₃), and —CH₂C≡C(CH₂CH₃) among others.

The term “acyl” as used herein refers to a group containing a carbonyl moiety wherein the group is bonded via the carbonyl carbon atom. The carbonyl carbon atom is bonded to a hydrogen forming a “formyl” group or is bonded to another carbon atom, which can be part of an alkyl, aryl, aralkyl cycloalkyl, cycloalkylalkyl, heterocyclyl, heterocyclylalkyl, heteroaryl, heteroarylalkyl group or the like. An acyl group can include 0 to about 12, 0 to about 20, or 0 to about 40 additional carbon atoms bonded to the carbonyl group. An acyl group can include double or triple bonds within the meaning herein. An acryloyl group is an example of an acyl group. An acyl group can also include heteroatoms within the meaning herein. A nicotinoyl group (pyridyl-3-carbonyl) is an example of an acyl group within the meaning herein. Other examples include acetyl, benzoyl, phenylacetyl, pyridylacetyl, cinnamoyl, and acryloyl groups and the like. When the group containing the carbon atom that is bonded to the carbonyl carbon atom contains a halogen, the group is termed a “haloacyl” group. An example is a trifluoroacetyl group.

The term “cycloalkyl” as used herein refers to cyclic alkyl groups such as, but not limited to, cyclopropyl, cyclobutyl, cyclopentyl, cyclohexyl, cycloheptyl, and cyclooctyl groups. In some embodiments, the cycloalkyl group can have 3 to about 8-12 ring members, whereas in other embodiments the number of ring carbon atoms range from 3 to 4, 5, 6, or 7. Cycloalkyl groups further include polycyclic cycloalkyl groups such as, but not limited to, norbornyl, adamantyl, bornyl, camphenyl, isocamphenyl, and carenyl groups, and fused rings such as, but not limited to, decalinyl, and the like. Cycloalkyl groups also include rings that are substituted with straight or branched chain alkyl groups as defined herein. Representative substituted cycloalkyl groups can be mono-substituted or substituted more than once, such as, but not limited to, 2,2-, 2,3-, 2,4-2,5- or 2,6-disubstituted cyclohexyl groups or mono-, di- or tri-substituted norbornyl or cycloheptyl groups, which can be substituted with, for example, amino, hydroxy, cyano, carboxy, nitro, thio, alkoxy, and halogen groups. The term “cycloalkenyl” alone or in combination denotes a cyclic alkenyl group.

The term “aryl” as used herein refers to cyclic aromatic hydrocarbon groups that do not contain heteroatoms in the ring. Thus aryl groups include, but are not limited to, phenyl, azulenyl, heptalenyl, biphenyl, indacenyl, fluorenyl, phenanthrenyl, triphenylenyl, pyrenyl, naphthacenyl, chrysenyl, biphenylenyl, anthracenyl, and naphthyl groups. In some embodiments, aryl groups contain about 6 to about 14 carbons in the ring portions of the groups. Aryl groups can be unsubstituted or substituted, as defined herein. Representative substituted aryl groups can be mono-substituted or substituted more than once, such as, but not limited to, a phenyl group substituted at any one or more of 2-, 3-, 4-, 5-, or 6-positions of the phenyl ring, or a naphthyl group substituted at any one or more of 2- to 8-positions thereof.

The term “aralkyl” as used herein refers to alkyl groups as defined herein in which a hydrogen or carbon bond of an alkyl group is replaced with a bond to an aryl group as defined herein. Representative aralkyl groups include benzyl and phenylethyl groups and fused (cycloalkylaryl)alkyl groups such as 4-ethyl-indanyl. Aralkenyl groups are alkenyl groups as defined herein in which a hydrogen or carbon bond of an alkyl group is replaced with a bond to an aryl group as defined herein.

The term “heterocyclyl” as used herein refers to aromatic and non-aromatic ring compounds containing three or more ring members, of which one or more is a heteroatom such as, but not limited to, N, O, and S. Thus, a heterocyclyl can be a cycloheteroalkyl, or a heteroaryl, or if polycyclic, any combination thereof. In some embodiments, heterocyclyl groups include 3 to about 20 ring members, whereas other such groups have 3 to about 15 ring members. A heterocyclyl group designated as a C₂-heterocyclyl can be a 5-ring with two carbon atoms and three heteroatoms, a 6-ring with two carbon atoms and four heteroatoms and so forth. Likewise a C₄-heterocyclyl can be a 5-ring with one heteroatom, a 6-ring with two heteroatoms, and so forth. The number of carbon atoms plus the number of heteroatoms equals the total number of ring atoms. A heterocyclyl ring can also include one or more double bonds. A heteroaryl ring is an embodiment of a heterocyclyl group. The phrase “heterocyclyl group” includes fused ring species including those that include fused aromatic and non-aromatic groups. For example, a dioxolanyl ring and a benzdioxolanyl ring system (methylenedioxyphenyl ring system) are both heterocyclyl groups within the meaning herein. The phrase also includes polycyclic ring systems containing a heteroatom such as, but not limited to, quinuclidyl. Heterocyclyl groups can be unsubstituted, or can be substituted as discussed herein. Heterocyclyl groups include, but are not limited to, pyrrolidinyl, piperidinyl, piperazinyl, morpholinyl, pyrrolyl, pyrazolyl, triazolyl, tetrazolyl, oxazolyl, isoxazolyl, thiazolyl, pyridinyl, thiophenyl, benzothiophenyl, benzofuranyl, dihydrobenzofuranyl, indolyl, dihydroindolyl, azaindolyl, indazolyl, benzimidazolyl, azabenzimidazolyl, benzoxazolyl, benzothiazolyl, benzothiadiazolyl, imidazopyridinyl, isoxazolopyridinyl, thianaphthalenyl, purinyl, xanthinyl, adeninyl, guaninyl, quinolinyl, isoquinolinyl, tetrahydroquinolinyl, quinoxalinyl, and quinazolinyl groups. Representative substituted heterocyclyl groups can be mono-substituted or substituted more than once, such as, but not limited to, piperidinyl or quinolinyl groups, which are 2-, 3-, 4-, 5-, or 6-substituted, or disubstituted with groups such as those listed herein.

The term “heteroaryl” as used herein refers to aromatic ring compounds containing 5 or more ring members, of which, one or more is a heteroatom such as, but not limited to, N, O, and S; for instance, heteroaryl rings can have 5 to about 8-12 ring members. A heteroaryl group is a variety of a heterocyclyl group that possesses an aromatic electronic structure. A heteroaryl group designated as a C₂-heteroaryl can be a 5-ring with two carbon atoms and three heteroatoms, a 6-ring with two carbon atoms and four heteroatoms and so forth. Likewise a C₄-heteroaryl can be a 5-ring with one heteroatom, a 6-ring with two heteroatoms, and so forth. The number of carbon atoms plus the number of heteroatoms sums up to equal the total number of ring atoms. Heteroaryl groups include, but are not limited to, groups such as pyrrolyl, pyrazolyl, triazolyl, tetrazolyl, oxazolyl, isoxazolyl, thiazolyl, pyridinyl, thiophenyl, benzothiophenyl, benzofuranyl, indolyl, azaindolyl, indazolyl, benzimidazolyl, azabenzimidazolyl, benzoxazolyl, benzothiazolyl, benzothiadiazolyl, imidazopyridinyl, isoxazolopyridinyl, thianaphthalenyl, purinyl, xanthinyl, adeninyl, guaninyl, quinolinyl, isoquinolinyl, tetrahydroquinolinyl, quinoxalinyl, and quinazolinyl groups. Heteroaryl groups can be unsubstituted, or can be substituted with groups as is discussed herein. Representative substituted heteroaryl groups can be substituted one or more times with groups such as those listed herein.

Additional examples of aryl and heteroaryl groups include but are not limited to phenyl, biphenyl, indenyl, naphthyl (1-naphthyl, 2-naphthyl), N-hydroxytetrazolyl, N-hydroxytriazolyl, N-hydroxyimidazolyl, anthracenyl (1-anthracenyl, 2-anthracenyl, 3-anthracenyl), thiophenyl (2-thienyl, 3-thienyl), furyl (2-furyl, 3-furyl), indolyl, oxadiazolyl, isoxazolyl, quinazolinyl, fluorenyl, xanthenyl, isoindanyl, benzhydryl, acridinyl, thiazolyl, pyrrolyl (2-pyrrolyl), pyrazolyl (3-pyrazolyl), imidazolyl (1-imidazolyl, 2-imidazolyl, 4-imidazolyl, 5-imidazolyl), triazolyl (1,2,3-triazol-1-yl, 1,2,3-triazol-2-yl 1,2,3-triazol-4-yl, 1,2,4-triazol-3-yl), oxazolyl (2-oxazolyl, 4-oxazolyl, 5-oxazolyl), thiazolyl (2-thiazolyl, 4-thiazolyl, 5-thiazolyl), pyridyl (2-pyridyl, 3-pyridyl, 4-pyridyl), pyrimidinyl (2-pyrimidinyl, 4-pyrimidinyl, 5-pyrimidinyl, 6-pyrimidinyl), pyrazinyl, pyridazinyl (3-pyridazinyl, 4-pyridazinyl, 5-pyridazinyl), quinolyl (2-quinolyl, 3-quinolyl, 4-quinolyl, 5-quinolyl, 6-quinolyl, 7-quinolyl, 8-quinolyl), isoquinolyl (1-isoquinolyl, 3-isoquinolyl, 4-isoquinolyl, 5-isoquinolyl, 6-isoquinolyl, 7-isoquinolyl, 8-isoquinolyl), benzo[b]furanyl (2-benzo[b]furanyl, 3-benzo[b]furanyl, 4-benzo[b]furanyl, 5-benzo[b]furanyl, 6-benzo[b]furanyl, 7-benzo[b]furanyl), 2,3-dihydro-benzo[b]furanyl (2-(2,3-dihydro-benzo[b]furanyl), 3-(2,3-dihydro-benzo[b]furanyl), 4-(2,3-dihydro-benzo[b]furanyl), 5-(2,3-dihydro-benzo[b]furanyl), 6-(2,3-dihydro-benzo[b]furanyl), 7-(2,3-dihydro-benzo[b]furanyl), benzo[b]thiophenyl (2-benzo[b]thiophenyl, 3-benzo[b]thiophenyl, 4-benzo[b]thiophenyl, 5-benzo[b]thiophenyl, 6-benzo[b]thiophenyl, 7-benzo[b]thiophenyl), 2,3-dihydro-benzo[b]thiophenyl, (2-(2,3-dihydro-benzo[b]thiophenyl), 3-(2,3-dihydro-benzo[b]thiophenyl), 4-(2,3-dihydro-benzo[b]thiophenyl), 5-(2,3-dihydro-benzo[b]thiophenyl), 6-(2,3-dihydro-benzo[b]thiophenyl), 7-(2,3-dihydro-benzo[b]thiophenyl), indolyl (1-indolyl, 2-indolyl, 3-indolyl, 4-indolyl, 5-indolyl, 6-indolyl, 7-indolyl), indazole (1-indazolyl, 3-indazolyl, 4-indazolyl, 5-indazolyl, 6-indazolyl, 7-indazolyl), benzimidazolyl (1-benzimidazolyl, 2-benzimidazolyl, 4-benzimidazolyl, 5-benzimidazolyl, 6-benzimidazolyl, 7-benzimidazolyl, 8-benzimidazolyl), benzoxazolyl (1-benzoxazolyl, 2-benzoxazolyl), benzothiazolyl (1-benzothiazolyl, 2-benzothiazolyl, 4-benzothiazolyl, 5-benzothiazolyl, 6-benzothiazolyl, 7-benzothiazolyl), carbazolyl (1-carbazolyl, 2-carbazolyl, 3-carbazolyl, 4-carbazolyl), 5H-dibenz[b,f]azepine (5H-dibenz[b,f]azepin-1-yl, 5H-dibenz[b,f]azepine-2-yl, 5H-dibenz[b,f]azepine-3-yl, 5H-dibenz[b,f]azepine-4-yl, 5H-dibenz[b,f]azepine-5-yl), 10,11-dihydro-5H-dibenz[b,f]azepine (10,11-dihydro-5H-dibenz[b,f]azepine-1-yl, 10,11-dihydro-5H-dibenz[b,f]azepine-2-yl, 10,11-dihydro-5H-dibenz[b,f]azepine-3-yl, 10,11-dihydro-5H-dibenz[b,f]azepine-4-yl, 10,11-dihydro-5H-dibenz[b,f]azepine-5-yl), and the like.

The term “heterocyclylalkyl” as used herein refers to alkyl groups as defined herein in which a hydrogen or carbon bond of an alkyl group as defined herein is replaced with a bond to a heterocyclyl group as defined herein. Representative heterocyclyl alkyl groups include, but are not limited to, furan-2-yl methyl, furan-3-yl methyl, pyridine-3-yl methyl, tetrahydrofuran-2-yl ethyl, and indol-2-yl propyl.

The term “heteroarylalkyl” as used herein refers to alkyl groups as defined herein in which a hydrogen or carbon bond of an alkyl group is replaced with a bond to a heteroaryl group as defined herein.

The term “alkoxy” as used herein refers to an oxygen atom connected to an alkyl group, including a cycloalkyl group, as are defined herein. Examples of linear alkoxy groups include but are not limited to methoxy, ethoxy, propoxy, butoxy, pentyloxy, hexyloxy, and the like. Examples of branched alkoxy include but are not limited to isopropoxy, sec-butoxy, tert-butoxy, isopentyloxy, isohexyloxy, and the like. Examples of cyclic alkoxy include but are not limited to cyclopropyloxy, cyclobutyloxy, cyclopentyloxy, cyclohexyloxy, and the like. An alkoxy group can include about 1 to about 12, about 1 to about 20, or about 1 to about 40 carbon atoms bonded to the oxygen atom, and can further include double or triple bonds, and can also include heteroatoms. For example, an allyloxy group or a methoxyethoxy group is also an alkoxy group within the meaning herein, as is a methylenedioxy group in a context where two adjacent atoms of a structure are substituted therewith.

The term “amine” as used herein refers to primary, secondary, and tertiary amines having, e.g., the formula N(group)₃ wherein each group can independently be H or non-H, such as alkyl, aryl, and the like. Amines include but are not limited to R—NH₂, for example, alkylamines, arylamines, alkylarylamines; R₂NH wherein each R is independently selected, such as dialkylamines, diarylamines, aralkylamines, heterocyclylamines and the like; and R₃N wherein each R is independently selected, such as trialkylamines, dialkylarylamines, alkyldiarylamines, triarylamines, and the like. The term “amine” also includes ammonium ions as used herein.

The term “amino group” as used herein refers to a substituent of the form —NH₂, —NHR, —NR₂, —NR₃⁺, wherein each R is independently selected, and protonated forms of each, except for —NR₃⁺, which cannot be protonated. Accordingly, any compound substituted with an amino group can be viewed as an amine. An “amino group” within the meaning herein can be a primary, secondary, tertiary, or quaternary amino group. An “alkylamino” group includes a monoalkylamino, dialkylamino, and trialkylamino group.

The terms “halo,” “halogen,” or “halide” group, as used herein, by themselves or as part of another substituent, mean, unless otherwise stated, a fluorine, chlorine, bromine, or iodine atom.

The term “haloalkyl” group, as used herein, includes mono-halo alkyl groups, poly-halo alkyl groups wherein all halo atoms can be the same or different, and per-halo alkyl groups, wherein all hydrogen atoms are replaced by halogen atoms, such as fluoro. Examples of haloalkyl include trifluoromethyl, 1,1-dichloroethyl, 1,2-dichloroethyl, 1,3-dibromo-3,3-difluoropropyl, perfluorobutyl, and the like.

The terms “epoxy-functional” or “epoxy-substituted” as used herein refers to a functional group in which an oxygen atom, the epoxy substituent, is directly attached to two adjacent carbon atoms of a carbon chain or ring system. Examples of epoxy-substituted functional groups include, but are not limited to, 2,3-epoxypropyl, 3,4-epoxybutyl, 4,5-epoxypentyl, 2,3-epoxypropoxy, epoxypropoxypropyl, 2-glycidoxyethyl, 3-glycidoxypropyl, 4-glycidoxybutyl, 2-(glycidoxycarbonyl)propyl, 3-(3,4-epoxycylohexyl)propyl, 2-(3,4-epoxycyclohexyl)ethyl, 2-(2,3-epoxycylopentyl)ethyl, 2-(4-methyl-3,4-epoxycyclobexyl)propyl, 2-(3,4-epoxy-3-methylcylohexyl)-2-methylethyl, and 5,6-epoxyhexyl.

The term “monovalent” as used herein refers to a substituent connecting via a single bond to a substituted molecule. When a substituent is monovalent, such as, for example, F or Cl, it is bonded to the atom it is substituting by a single bond.

The term “hydrocarbon” or “hydrocarbyl” as used herein refers to a molecule or functional group that includes carbon and hydrogen atoms. The term can also refer to a molecule or functional group that normally includes both carbon and hydrogen atoms but wherein all the hydrogen atoms are substituted with other functional groups.

As used herein, the term “hydrocarbyl” refers to a functional group derived from a straight chain, branched, or cyclic hydrocarbon, and can be alkyl, alkenyl, alkynyl, aryl, cycloalkyl, acyl, or any combination thereof. Hydrocarbyl groups can be shown as (Cₐ-C_{b})hydrocarbyl, wherein a and b are integers and mean having any of a to b number of carbon atoms. For example, (C₁-C₄)hydrocarbyl means the hydrocarbyl group can be methyl (C₁), ethyl (C₂), propyl (C₃), or butyl (C₄), and (C₀-C_{b})hydrocarbyl means in certain embodiments there is no hydrocarbyl group.

The term “solvent” as used herein refers to a liquid that can dissolve a solid, liquid, or gas. Non-limiting examples of solvents are silicones, organic compounds, water, alcohols, ionic liquids, and supercritical fluids.

The term “independently selected from” as used herein refers to referenced groups being the same, different, or a mixture thereof, unless the context clearly indicates otherwise. Thus, under this definition, the phrase “X¹, X², and X³ are independently selected from noble gases” would include the scenario where, for example, X¹, X², and X³ are all the same, where X¹, X², and X³ are all different, where X¹ and X² are the same but X³ is different, and other analogous permutations.

The term “room temperature” as used herein refers to a temperature of about 15° C. to 28° C.

The term “standard temperature and pressure” as used herein refers to 20° C. and 101 kPa.

### Monomers for Holographic Recording

Compounds of formula (I) or otherwise described herein can be prepared by the general schemes described herein, using the synthetic method known by those skilled in the art. The following examples illustrate non-limiting embodiments of the compound(s) described herein and their preparation.

In certain embodiments, a composition for a monomer suitable for holographic recording includes:
at least one polymer;
a polymer binder comprising a plurality of allyl groups; and
at least one monomer of formula (I):

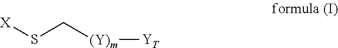

and at least one monomer of formula (II):

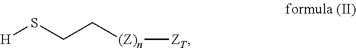

wherein:
each occurrence of X is independently H, optionally substituted C₁₋₁₂ hydrocarbyl, or optionally substituted C₆₋₁₄ aryl;
each Y is independently —S—, —CH₂—, —CH₂CH₂—, —CH(CH₃)CH₂—, —CH₂CH(CH₃)—, —CH(SH)—, —CH[O—CH₂—CH═CH₂]—, or —CH[O—CH₂—C≡CH]—;
each Y_{T} is independently H, —SH, —CH₂SH, —CH═CH₂, —C≡CH, or optionally substituted C₆₋₁₄ aryl;
each Z is independently —S—, —CH₂, —CH₂CH₂—, —CH(CH₃)CH₂—, —CH₂CH(CH₃)—, or —CH(SH)—;
each Z_{T} is independently H, —SH or —CH₂SH;
m is an integer ranging from 0 to 100; and
n is an integer ranging from 0 to 100.

In the monomer of formula (I), (Y)m-Y_{T} means a series of ‘m’ Y moieties bonded to each other, with a terminal Y_{T} moiety. Thus, for example, (Y)₂—Y_{T} means Y—Y—Y_{T}, where each Y and Y_{T} is independently chosen as described herein. Similarly, in the monomer of formula (II), (Z)₂—Z_{T} means Z—Z—Z_{T}, where each Z_{T} is independently chosen as described herein. In the monomers of formula (I) and formula (II), the terminal Y_{T} or Z_{T} group is chosen such that a chemically stable compound is formed. In various embodiments, the terminal Y_{T} group can be optionally substituted C₆₋₁₄ aryl. In various embodiments, the terminal Z_{T} group is —SH or —CH₂SH.

In one embodiment, the polymer is a linear polyurethane. Other suitable polymers can include those useful as a medium for holographic recording as described herein and that are known in the art. The polymer can be a block co-polymer, in some embodiments. Suitable block co-polymers can include polycaprolactone-block-polytetrahydrofuran-block-polycaprolactone (Mₙ˜2000), as described herein.

In one embodiment, polymer binder contains about 0 to about 80 mol % allyl groups. In one embodiment, the polymer binder contains about 0, 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, or about 100 mol % of allyl groups. In one embodiment, the polymer comprises a polycaprolactone-block-polytetrahydrofuran-block-polycaprolactone. The mol % of allyl groups is, various embodiments, relative to the total moles of allyl containing monomer/binder and the block-copolymer.

In various embodiments, the ratio of the monomer of formula (I) to the monomer of formula (II) is about 9:1 to about 1:9. The ratio of formula (I):formula (II) can take on any numeric value between 9:1 and 1:9, and in various embodiments the ratio of formula (I):formula (II) can be about 9:1, 8.5:1.5, 8:2, 7.5:2.5, 7:3, 6.5:3.5, 6:4, 5.5:4.5, 1:1, 4.5:5.5, 4:6, 3.5:6, 3:7, 2.5:7.5, 2:8, 1.5:8.5, or about 1:9. In various embodiments, the ratio of monomer of formula (I) to the monomer of formula (II) is the stoichiometric ratio between thiol groups in formula (II) and ene or yne groups in formula (I).

In various embodiments, (Z)ₙ includes at least one —SH moiety. In various embodiments, (Z)ₙ includes at least two —SH moieties. In various embodiments, (Z)ₙ includes at least three —SH moieties. In various embodiments, the monomer of formula (II) is selected from the group consisting of:

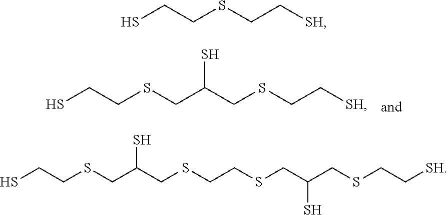

In various embodiments, X can be a C₆₋₁₀ aryl. In, some embodiments, X is phenyl. In various embodiments, (Y)ₘ is a linear chain. In one embodiment, (Y)ₘ can be at least one —CH(O—CH₂—CH═CH₂)— or —CH(O—CH₂—C≡CH)— moiety. In another embodiment, (Y)ₘ can be at least two independently selected moieties from —CH(O—CH₂—CH═CH₂)— and CH(O—CH₂—C≡CH)—.

In certain embodiments, the monomer of formula (I) is selected from the group consisting of:

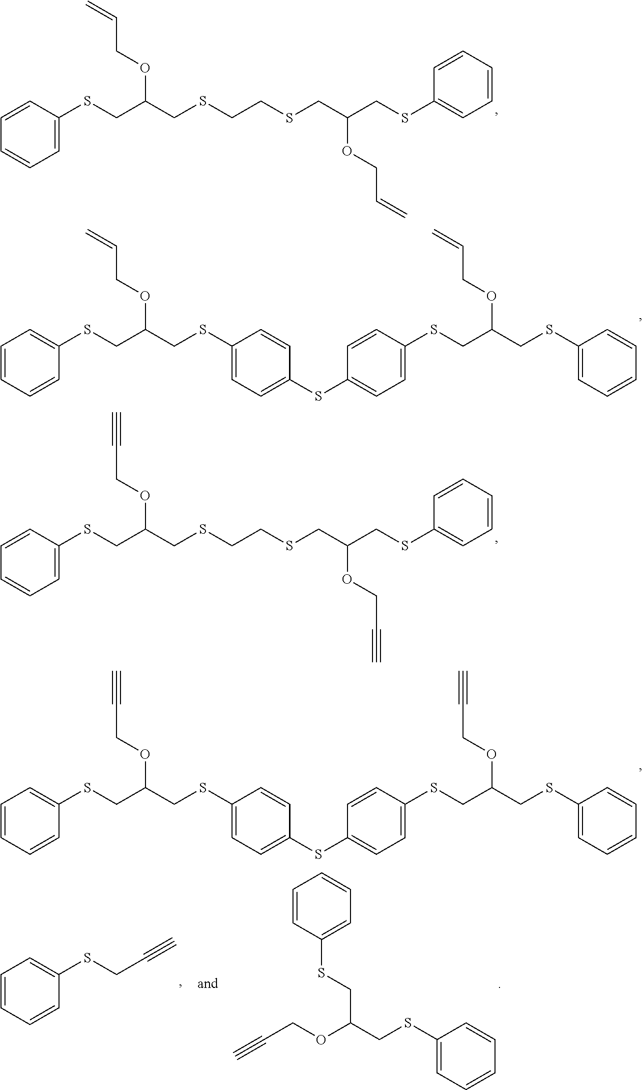

In one embodiment, the monomer of formula (I) and the monomer of formula (II) in total can be about 1 to 80% (w/w) of the composition. In some embodiments, the monomer can be about 0, 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, or about 80% (w/w) of the composition.

In one embodiment, the composition described herein is polymerized. The polymerized composition can be polymerized, in some embodiments, using light, such as laser light, photoinitiators, radical initiators, transition metal complexes, and the like.

In various embodiments, the holograms produced by the claim methods have a refractive index modulation (Δn) of about 0.01 to about 0.06. In one embodiment, the holograms described herein have a refractive index modulation (Δn) of about 0.01, 0.015, 0.02, 0.025, 0.03, 0.035, 0.04, 0.045, 0.05, 0.055, or about 0.06. In some embodiments, the monomers of formula (I) and formula (II), together with the polymer binder, form a solution.

In one embodiment, in the polymerized composition, the plurality of allyl groups and the monomer are cross-linked. The cross-linking can be between, for example, the allyl groups of the polymer binder and one or more thiol, allyl, or propargyl groups in the monomer. In some embodiments, the un-polymerized composition described herein can be cast as a film.

The refractive index of the network polymers can be further extended compared to that of the conventional high refractive index polymer systems via the formation of thioether linkages. Toward this goal, a series of high refractive index writing monomers containing thiol, ene and yne functionalities were designed and synthesized as described herein. Each monomer contains a flexible high refractive index core containing aryl and/or thioether groups. Utilizing the advantages of step-growth thiol-ene and thiol-yne ‘click’ reaction such as negligible oxygen sensitivity and reduced shrinkage, an excellent control over the material properties such as refractive index, dispersion, viscosity, glass transition temperature, and so forth, can be achieved.

In some embodiments, the monomers described herein displayed high refractive indices within the range of 1.59-1.67. Photopolymerization of a neat thiol-ene and thiol-yne resins using TPO photo initiator yielded n_{D} values in range of 1.6-1.7. An exemplary set of the RI values of the synthesized monomers and photopolymers measured at 589 nm wavelength are shown in Table 1 below.

TABLE 1
Table of refractive index measured at 25° C. and at the wavelength of
589 nm for the synthesized liquid writing monomers and their
photopolymer mixtures after curing.

| Ene/yne | | | | | | |
|---|---|---|---|---|---|---|
| Thiol [symbol] | Ene-1 1.593 | Ene-2 1.645 | Yne-1 1.590 | Yne-2 1.611 | Yne-3 1.603 | Yne-4 1.668 |
| Thiol-1 | — | — | — | 1.645 | 1.644 | 1.669 |
| (purchased) | | | | | | |
| 1.596 | | | | | | |
| Thol-2 | 1.633 | 1.669 | 1.666 | 1.649 | 1.655 | 1.689 |
| 1.636 | | | | | | |
| Thiol-3 | 1.636 | 1.669 | | 1.648 | 1.654 | 1.676 |
| 1.647 | | | | | | |

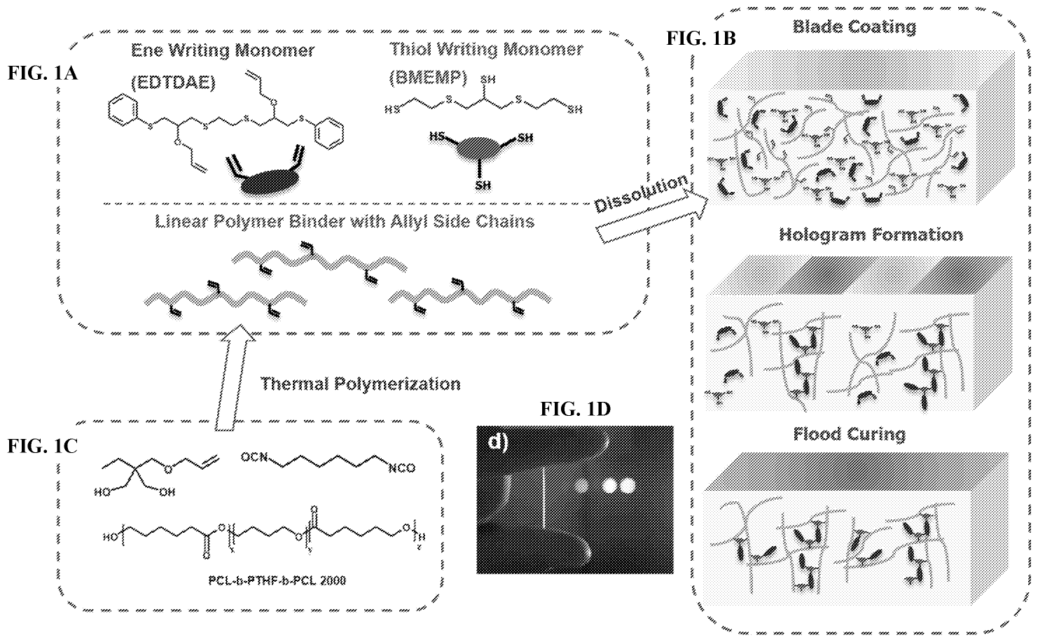

Here, a high dynamic range (Δn) holographic media based on thiol-ene click chemistry is devised and implemented as illustrated in FIGS. 1A-1D. 1,3-Bis(2-mercaptoethylthio)-2-mercaptopropane (BMEMP, trithiol, FIG. 1A) and 1,2-ethanedithiol-based diallyl ether (EDTDAE, diene, FIG. 1A) were selected as writing monomers, based on their ability to form high refractive index polymers (Table 2) through simple synthetic routes from readily available precursors.

TABLE 2
Refractive indices of writing monomers.

| Sample | BMEMP (Trithiol) | EDTDAE (Diene) |
|---|---|---|
| n_{f} (486.2 nm) | 1.6592 | 1.6094 |
| n_{d} (589.3 nm) | 1.6457 | 1.5954 |
| n_{c} (657.4 nm) | 1.6405 | 1.5900 |
| Abbe Number^{a} | 34.5 | 35.4 |

^{a}Abbe number = (n_{d} − 1)/(n_{f} − n_{c})

In an analogous approach to how holographic crosslinked binders are produced in conventional two-stage method, linear polyurethane binders were synthesized via step-growth polymerization of diols (trimethylolpropane allyl ether (TMPAE) and polyol Mw-2000) and diisocyanate (hexamethylene diisocyanate), which could be later dissolved in volatile organic solvent together with writing monomers and photoinitiator. Since orthogonal matrix formation and writing chemistries are required for the conventional two-stage strategy, it is difficult to use thiol-X reactions as the writing chemistry in combination with a conventionally polymerized, crosslinked urethane matrix due to the potential for cross reaction between the thiol from the writing monomer and the isocyanate from the binder.

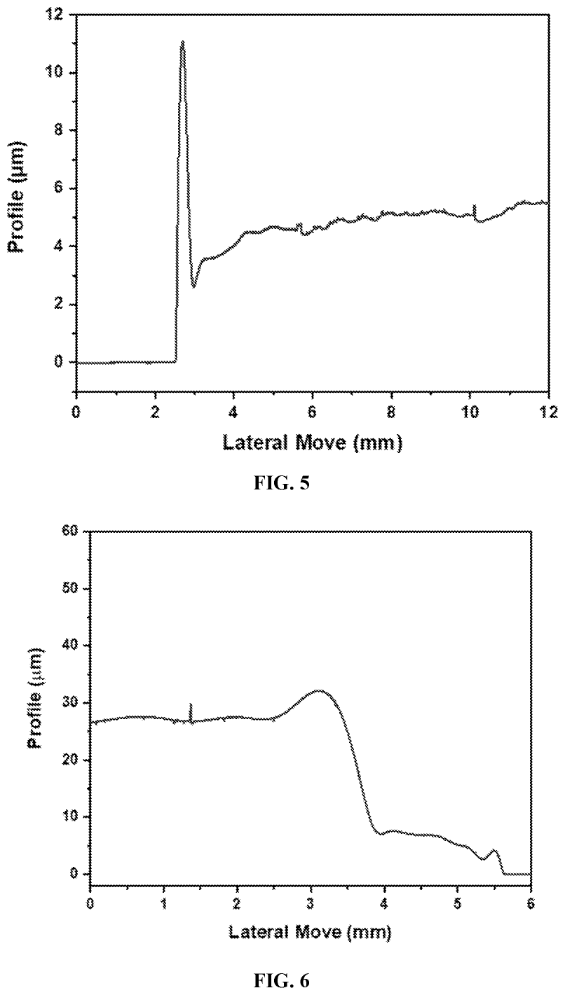

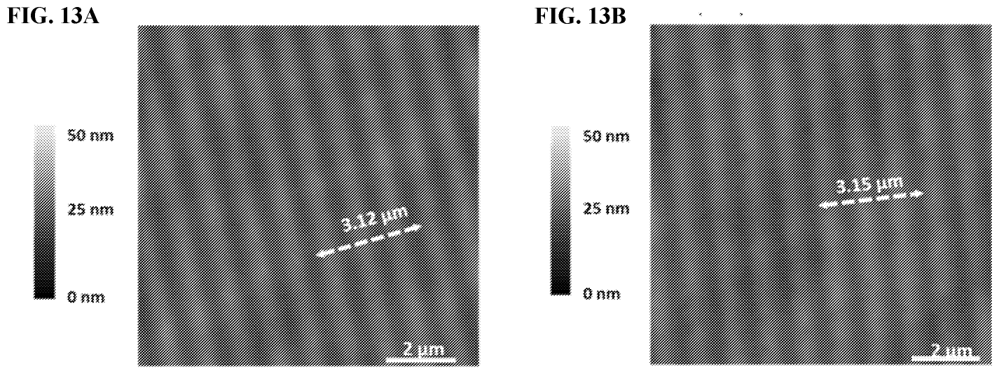

It was unexpectedly discovered that having the binders as linear polymers can decouple the two processes so that the formation of the low refractive index, urethane-based binder is performed in the absence of the thiol writing monomer. These polymers were formed with varying levels of TMPAE to facilitate attachment of the thiol-ene writing monomers and crosslinking of the matrix at different levels. After blade coating and thermal annealing, films with controllable thickness ranging from 3 to 30 microns were prepared and used for holographic recording. Transmission holograms were recorded by exposing the sample to two interfering 405 nm laser beams (FIG. 11). Simultaneously, the hologram diffraction efficiency is monitored in real-time using a 633 nm probe beam, to which the media is insensitive. Less than ten seconds of relatively low intensity light exposure is required to achieve the highest diffraction efficiency (DE) (FIG. 4), during which the thiol and ene monomers react with each other and with pendant ene functional groups on the linear polymer to form a crosslinked matrix only within the exposed regions of the film. After the exposure, angular playback is performed, using the same 633 nm probe beam to monitor diffraction efficiency as a function of angle detuning.

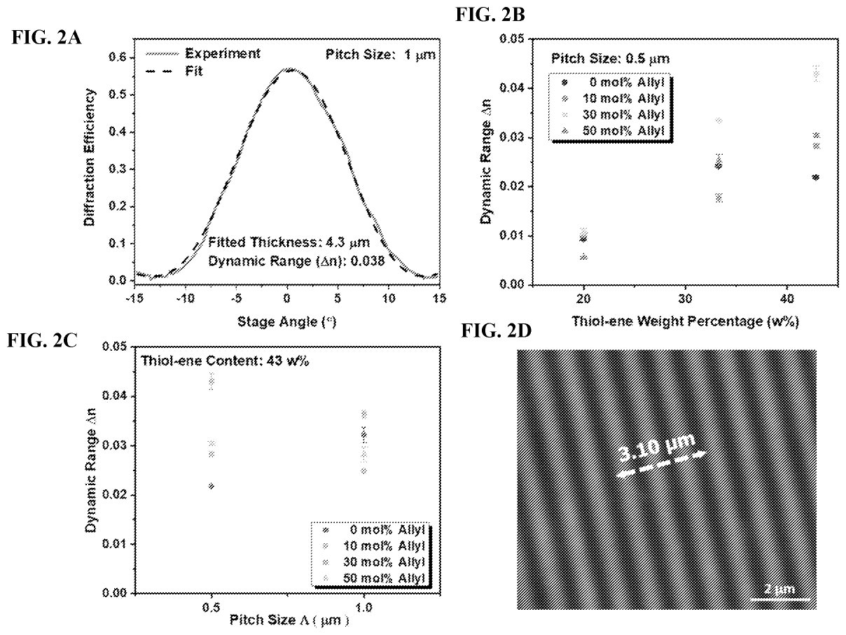

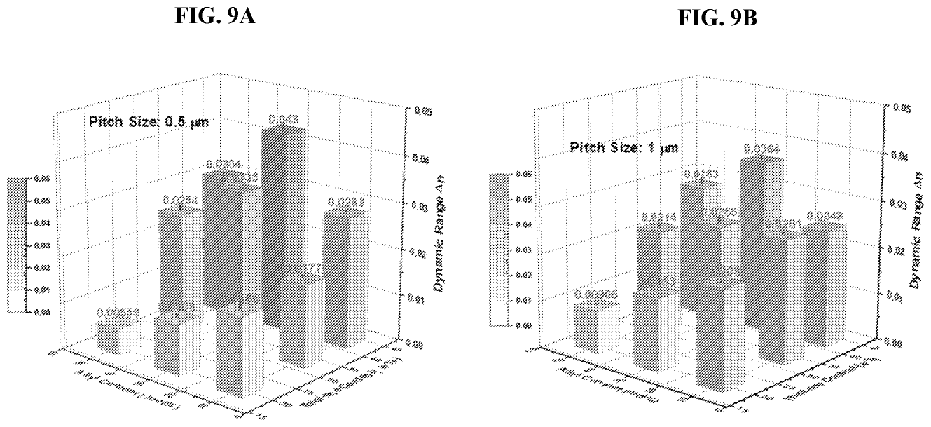

FIG. 2B shows the highest achievable holographic index modulation achieved at various loadings of the writing monomers (for transmission holograms with fringe spacing Λ=0.5 μm). As expected, the higher writing monomer loadings generally yield higher index modulations, in some cases as high as 0.04. The one exception is the control formulation in which the binder contains no allyl side groups. Here, the index modulation drops sharply when the writing monomer loading is increased to as high as 40 wt %. The conjecture is that, at this high loading, the writing monomer phase separates from the binder upon polymerization, reducing optical clarity and correspondingly the diffraction efficiency. When the allyl reactive sites were present on the linear polymer binder, however, the binder and writing polymer react together to form a single crosslinked network in the exposed regions, preventing phase separation and enabling the use of high monomer loadings. In order to elucidate the effect of the allyl side chain, the same data is replotted with allyl loading as the independent variable (FIGS. 7A-7B). In general, an optimal allyl content exists: while low allyl content presents insufficient anchoring, excess allyl may interfere with the thiol-ene photopolymerization.

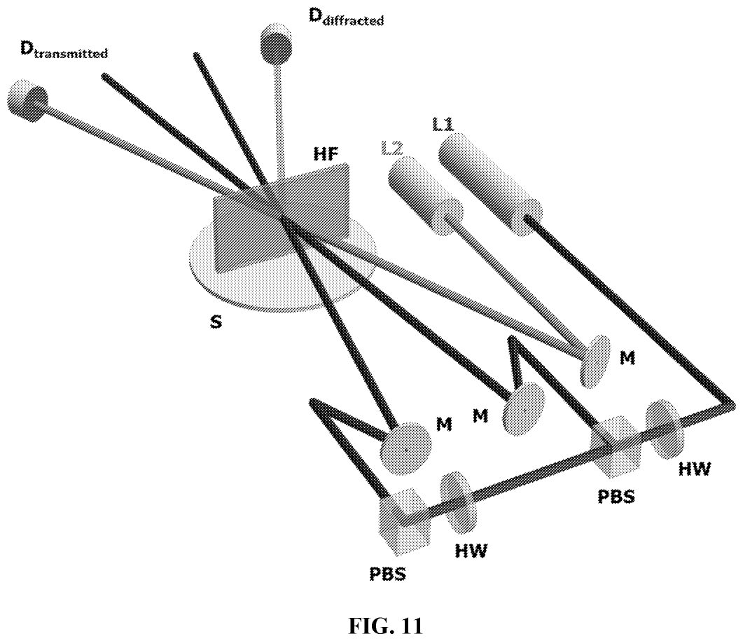

Next, diffusional blurring effects were assessed in the presence of the allyl reactive sites on the binder. To this end, holographic performance at two different spatial frequencies is compared (corresponding to pitch Λ=0.5 μm vs 1 μm, shown in FIGS. 7A-7B). In the absence of the allyl reactive sites, the index modulation falls off significantly at the higher spatial frequency, due to diffusional blurring. When the allyl reactive sites were present, the index modulation remains almost unchanged as a function of spatial frequency as seen in FIG. 2C. Through reaction, the writing polymer is effectively anchored to binder reactive sites and immobilized, yielding a significant reduction in diffusional blurring. FIGS. 9A-9B illustrate the performance of all formulations except the control group and shows impressive tunability of the thiol-ene based holograms in terms of dynamic range.

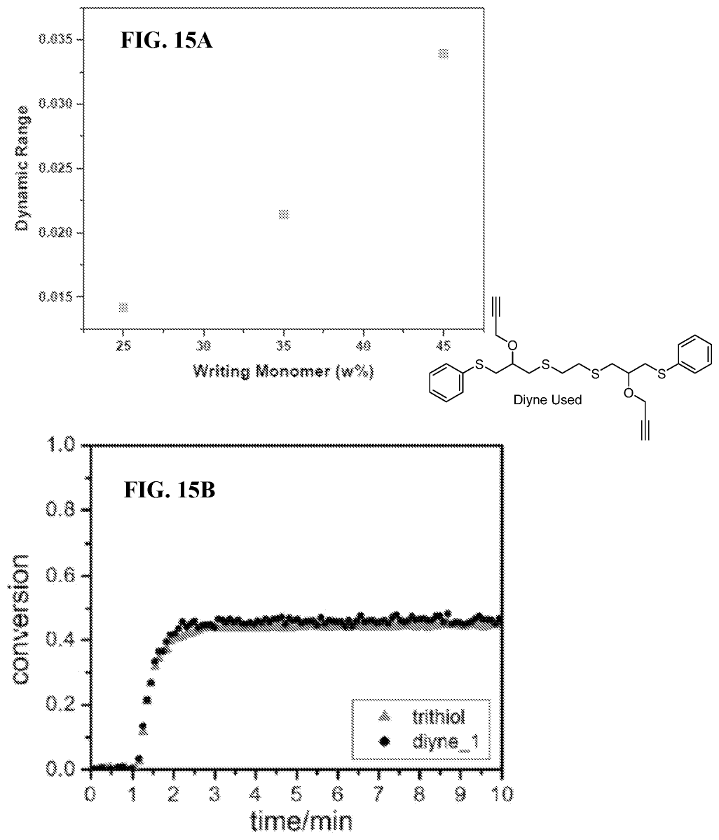

In FIG. 2D, atomic force microscopy (AFM) of small surface-relief variations enables direct visualization of recorded fringes. The measured fringe spacings agree with nominal values, and fringe uniformity is good for all formulations (FIGS. 13A-13B). The surface-relief features in FIGS. 13A-13B were on the order of 10 nm, making a negligible contribution to optical diffraction as compared to the volumetric index variations within the film. This observation is confirmed by applying index-matching fluid and a coverslip during holographic playback and achieving identical results.

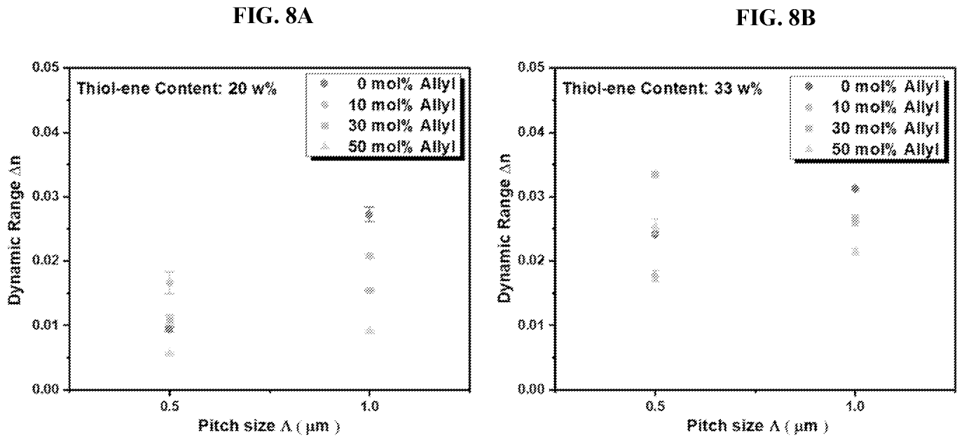

Finally, to demonstrate further the performance of this thiol-ene based recording media at a higher spatial frequency, reflection holograms were recorded. In general, index modulation is often sharply reduced at these smaller pitches, due to diffusional blurring. However, owing to the introduction of covalent chemical connections between the polymer binder and writing monomers, improved performance of reflection holograms was expected in this system. A single-beam Denisyuk configuration was used to record with a pitch Λ=140 nm for a nominal reflection notch around 405 nm. In one embodiment, a formulation from the previous transmission experiments was used here (30 mol % Allyl and 43 w % thiol-ene writing monomers). Thicker films of ˜25 μm were obtained via repeated blade coating, which yields acceptable surface profile (FIG. 6). FIG. 4B shows a typical hologram transmission spectrum (after a 10-seconds exposure). For comparison, the prediction of the Kogelnik coupled-wave model is also shown (note that index modulation and film thickness were chosen manually, rather than as least-squares fit parameters as before). This behavior suggests an index modulation in excess of 5×10⁻³ representing a significant drop from the larger-pitch transmission case (4×10⁻²) but still sufficient to achieve a diffraction efficiency of better than 90% in these relatively thin films. The spectrally broadened central notch is characteristic of Kogelnik overmodulation, indicating good grating uniformity throughout the sample thickness.

In summary, thiol-ene click chemistry in combination with a linear, functionalized polymer binder was implemented to fabricate holographic materials capable of achieving high dynamic range. Owing to the choice of linear low RI polyurethane matrix, a roll-to-roll blading coating method was used to prepare holographic films. A high dynamic range over 0.04 was obtained by incorporating optimal reactive allyl side chains into a linear polyurethane polymer binder, which addressed the diffusional blurring problem that arises at high spatial frequency. A remarkable overmodulated reflection hologram was demonstrated to prove the superior performance of the film in extreme high spatial frequency and reduced diffusional blurring.

### Methods of Recording Holograms

In one embodiment, a method of recording a hologram is provided. The method includes providing a composition containing a polymer binder a monomer of formula (I) and monomer of formula (II) as described herein and exposing the composition to laser irradiation to form a hologram. The laser irradiation can include using two laser beams from a suitable source such as shown in FIG. 11. Holograms can also be recorded using other art recognized methods. The holograms produced by the claimed methods can be used in applications such as, heads-up displays in vehicles and aircraft, holographic data storage, and as holographic optical elements.

The providing step can include, in some embodiments, coating an inert substrate with the film. Suitable inert substrates can include glass, plastic, metal, semi-conducting materials, ceramics, rubber, and combinations of these materials. In one embodiment, the exposing step can include cross-linking the polymer binder and the monomers of formula (I) and formula (II).

### High Refractive Index Photopolymers

In various embodiments, compounds of formula (I-A) and formula (II) can be cross-linked to form photopolymers with high refractive indices. High refractive index polymers (HRIPs) are recognized as an interesting alternative to silicon and glasses for various optoelectronic applications because of their light weight, ease of processability, low cost and versatility in control over material properties While significant progress has been made in the development of intrinsic HRIPs, the majority of these strategies rely on thermally driven polymerization techniques that suffer from a lack of optical transparency, spatial and temporal control.

Increasing the refractive index and crosslinking density of the network polymers without altering the molecular weight or core structure of the monomer is challenging. Although there exist scattered recent reports on thiolyne based photopolymers, far fewer applications and studies have, however, been directed towards scalable synthesis of high refractive index monomers and photopolymers. Based on the general synthetic protocol developed for high refractive index thiol-yne photopolymers, here, a set of high refractive index, low viscosity propargyl ethers is reported that form miscible resins with multifunctional thiols. Photopolymerization of these resin mixtures under mild conditions results in optically transparent films with refractive index values (nD) ranging from, in various embodiments, 1.60 to 1.75.

In various embodiments, a composition is provided. In certain embodiments, the composition includes:
at least one monomer of formula (I-A):

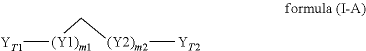

and at least one monomer of formula (II):

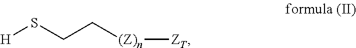

wherein:
each occurrence of X is independently H or optionally substituted C₆₋₁₄ aryl;
each occurrence of Y1 and Y2 is independently —S—, —CH₂—, —CH₂CH₂—, —CH(CH₃)CH₂—, —CH₂CH(CH₃)—, —CH(SH)—, —CH[O—CH₂—CH═CH₂]—, or —CH[O—CH₂—C≡CH]—;
each occurrence of Y_{T1} and Y_{T2} is independently H, —SH, —CH═CH₂, —C≡CH, or optionally substituted C₆₋₁₄ aryl;
each Z is independently —S—, —CH₂, —CH₂CH₂—, —CH(CH₃)CH₂—, —CH₂CH(CH₃)—, or —CH(SH)—;
each Z_{T} is independently H, —SH or —CH₂SH;
each m1 and m2 is independently an integer ranging from 0 to 100; and
n is an integer ranging from 0 to 100.

The composition containing at least one monomer of formula (I-A) and formula (II) can be polymerized using any of the conditions described herein. The polymerization can be photopolymerization accomplished by exposing a monomer composition to UV and/or visible light.

In various embodiments, the polymerized composition has a refractive index of about 1.63 to about 1.69. In various embodiments, the refractive index of the polymerized composition is at least about, equal to, greater than about 1.60, 1.61, 1.62, 1.63, 1.64, 1.65, 1.66, 1.67, 1.68, 1.69, 1.70, 1.71, 1.72, 1.73, 1.74, or about 1.75.

In various embodiments, (Z)ₙ—Z_{T} contains at least one —SH moiety. In various embodiments, (Z)ₙ—Z_{T} contains at least two —SH moieties.

In various embodiments, the monomer of formula (II) is selected from the group consisting of:

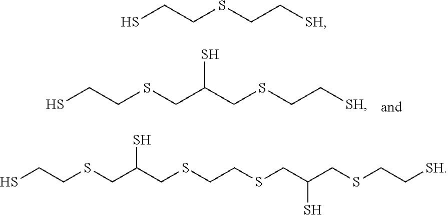

In various embodiments, m1 is 1, Y1 is —S—, and YT₁ is phenyl.

In various embodiments, at least one of (Y1)ₘ₁ and (Y2)ₘ₂ is a linear chain.

In various embodiments, at least one of (Y1)ₘ₁ and (Y2)ₘ₂ comprises at least one of —CH(O—CH₂—CH═CH₂)— or —CH(O—CH₂—C≡CH)—.

In various embodiments, at least one of (Y1)ₘ₁ and (Y2)ₘ₂ comprises at least two moieties independently selected from —CH(O—CH₂—CH═CH₂)— and —CH(O—CH₂—C≡CH)—. In various embodiments, Y_{T1} and Y_{T2} are —C≡CH.

In various embodiments, the monomer of formula (I-A) is selected from the group consisting of:

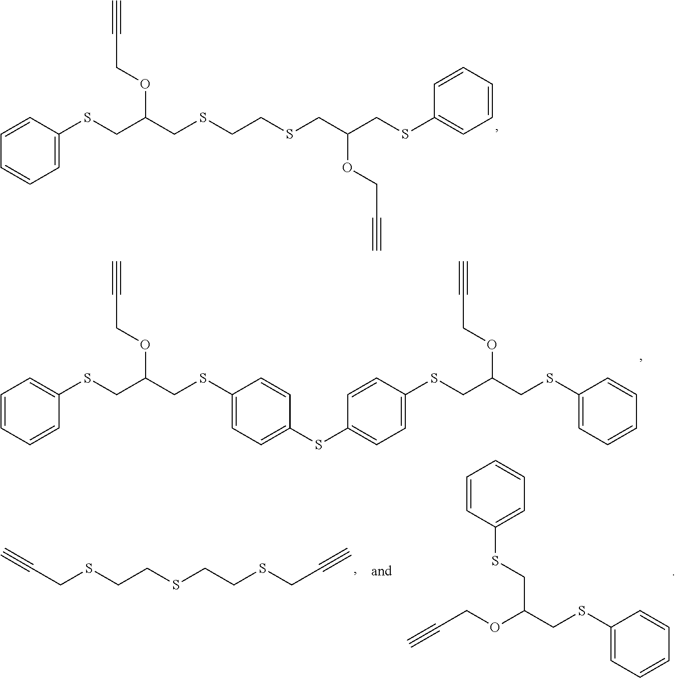 [SMILES: C#CCOC(CSCCSCC(CSc1ccccc1)OCC#C)CSc1ccccc1 ; C#CCOC(CSc1ccccc1)CSc1ccc(Sc2ccc(SCC(CSc3ccccc3)OCC#C)cc2)cc1 ; C#CCSCCSCCSCC#C ; C#CCOC(CSc1ccccc1)CSc1ccccc1]

A thoughtful utilization of various thiol-X click reactions in monomer synthesis not only allows for the incorporation of a high number of sulfide groups, but also results in the reaction having high yields with minimal side products. The monomers discussed here are synthesized starting form inexpensive and widely available raw materials and employ efficient utilization of thiolepoxide and thiol-halide click reactions (Scheme 1).

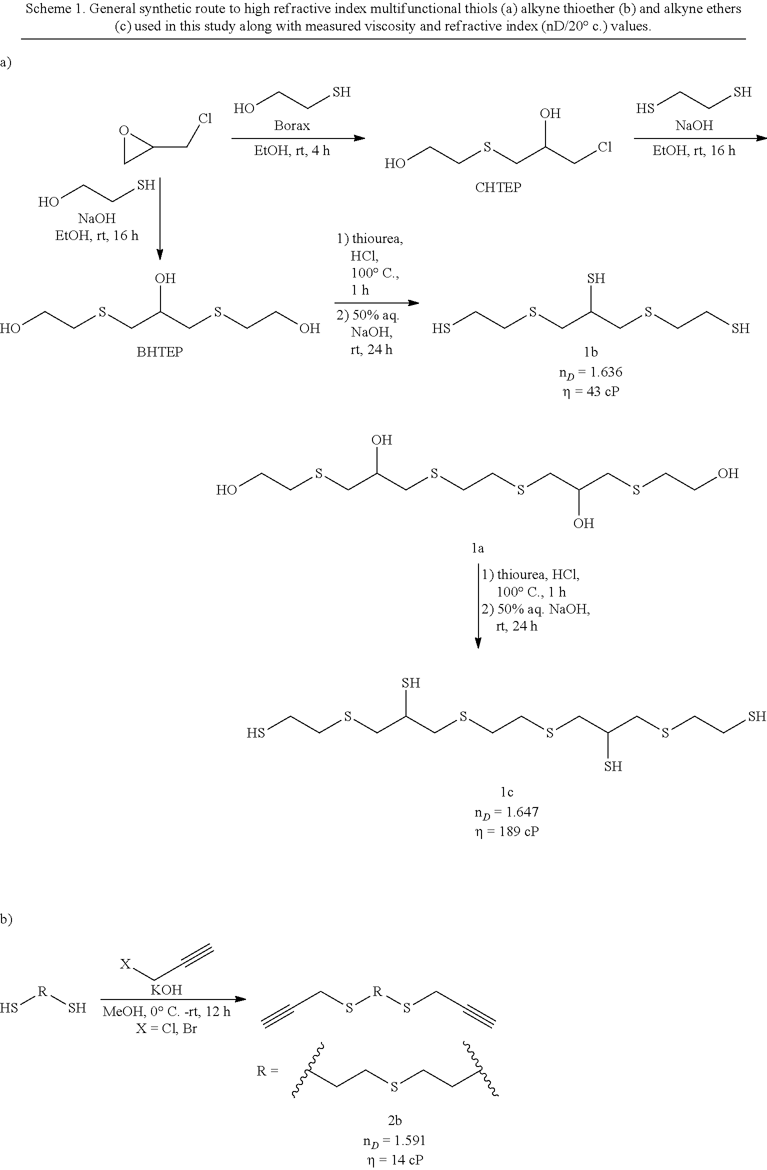

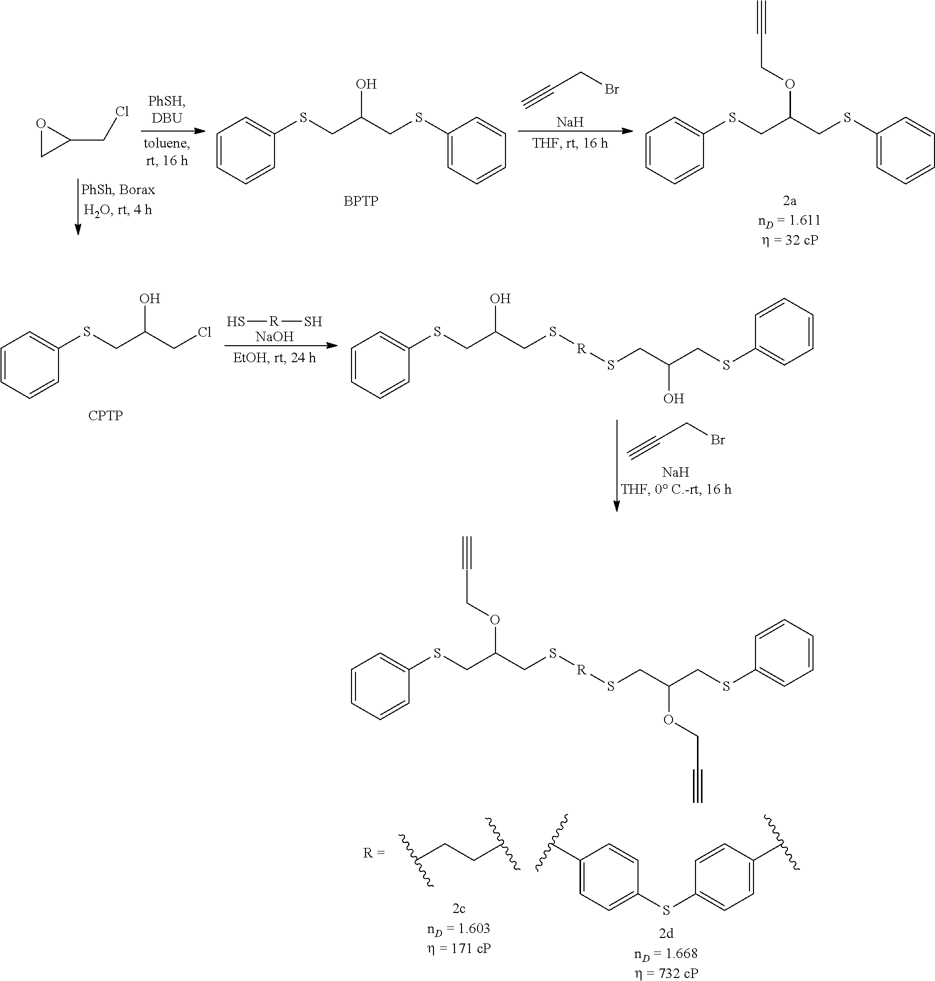

The general strategy developed here also provides a high degree of freedom over the choice of the backbone and polymerizable pendent groups. As can be seen form Scheme 2, the structure of each monomer differs in its core structure and the nature and position of the reactive functionalities. For example, the simplest yne monomer 2a only forms low cross-link density polymers as there is only one alkynal group but possesses low viscosity (32 cP) and high n (1.611) compared to rest of the aryl-containing monomers 2c and 2d.

The diyne monomer 2b has only sulfur in its backbone and no aryl groups. Though the refractive index is low (1.591), monomer 2b is sterically the least hindered and has the primary thiopropargyl functionality. Similarly, as we go from 1a to 1c in thiol monomers, the number of secondary thiol groups increases along with a corresponding increase in the refractive index. Specific material properties such as T_{g}, modulus, and hydrophobicity are easily tuned while maintaining a flexibility of the backbone with enhanced solubility. For example, flexible sulfide linkages throughout the monomer design facilitate a refractive index increase without substantially increasing the initial resin viscosity or sacrificing solubility or other optically desirable characteristics of a given monomer/resin.

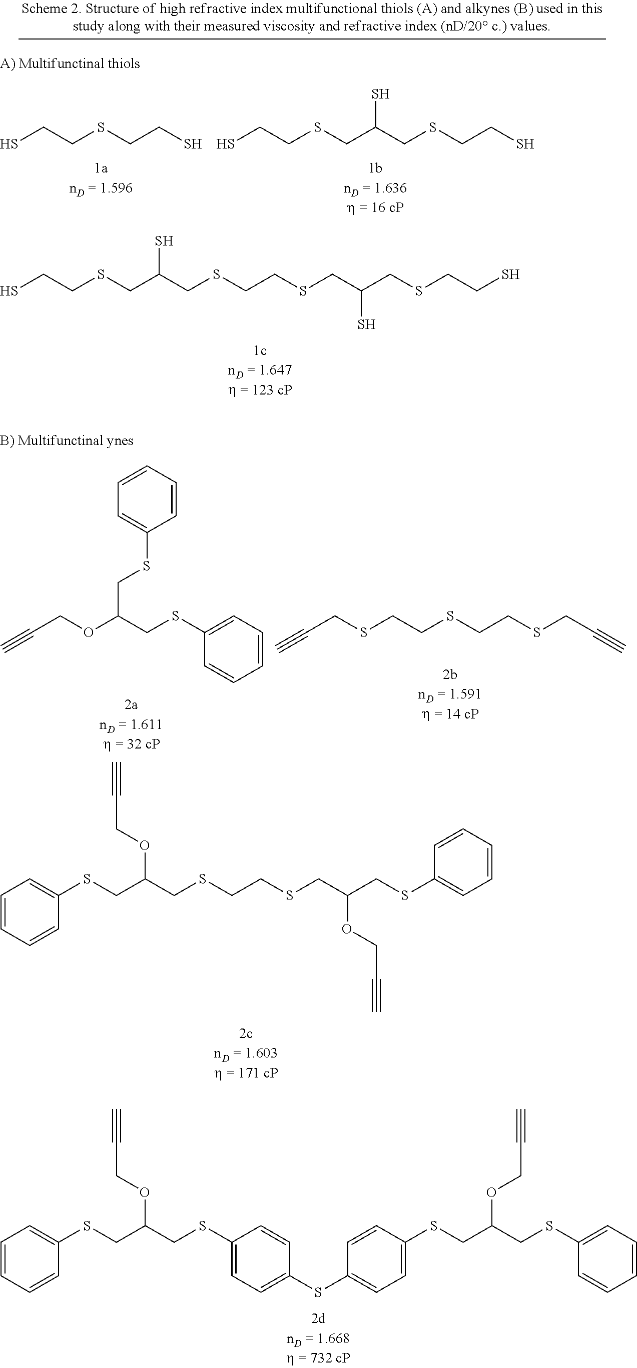

As the minimum thiol functionality required to form linear polymer via a thiol-yne click reaction is two, commercially available 2,2′-thiodiethanethiol (1a) with a refractive index (nD/20° C.) of 1.596 was used as the simplest dithiol. The trithiol (1b) and tetrathiol (1c) were obtained following the previous procedure starting from the ring opening reaction of epichlorohydrin with 2-mercaptoethanol under mild reaction conditions. In this manner, the reaction of one equivalent of 2-mercaptoethanol with epichlorohydrin in the presence of a catalytic amount of borax quantitatively and selectively yielded the monosubstituted product 1-chloro-3-(phenylthio)-2-propanol (CPTP) which was further reacted with one half equivalent of ethane dithiol to give the corresponding tetrahydroxy intermediate (TetraOH). Similarly, the trihydroxy intermediate (TriOH) was obtained by the reaction of two equivalents of 2-mercaptoethanol with epichlorohydrin in the presence NaOH as a base. The reaction of TriOH and TetraOH with thiourea was followed by the hydrolysis of the corresponding thiouronium salt using a 50% NaOH solution yielded the corresponding TriSH and TetraSH with an overall yield of 74% and 66%, respectively. Both monomers were isolated as colorless liquids with viscosities of 43 and 189 cP, and refractive index values (nD/20° C.) of 1.636 and 1.647, respectively. As each alkyne functional group is difunctional (i.e., able to react twice), the simplest alkyne monomer 2a used in this study was prepared in two high yielding steps starting from the reaction of epichlorohydrin and thiophenol. In the second step, deprotonation of the 2° alcohol BPTP was followed by alkylation with propargyl bromide and afforded low viscosity (32 cP) 2a in 91% yield with an accompanying refractive index value (nD/20° C.) of 1.611. In contrast, the monomer 2d with a viscosity of 14 cP, and refractive index value (nD/20° C.) of 1.591 was in turn prepared in single step in 85% yield via the alkylation of dithiol 1a with propargyl chloride in the presence of KOH as base.

The first step for the synthesis of the diyne monomers 2c and 2d involves the borax-catalyzed selective thiol-epoxide ring-opening reaction of epichlorohydrin with thiophenol. The reaction of epichlorohydrin with 1 equivalent of thiophenol gave the chloro intermediate, 1-chloro-3-(phenylthio)-2-proponal (CPTP), in excellent yields (>90%) as a colorless liquid. The chloro intermediate CPTP was further reacted with a high refractive index dithiol ‘core’ such as 1,2-ethane dithiol (EDT) and 4,4′-thiobisbenzenethiol (TBT) in the presence of NaOH as a base to yield the corresponding alcohols EDTOH and TBTOH, respectively, in more than 90% yields as a clear viscous liquid. Following this strategy, any high refractive index multifunctional thiols previously reported in the literature can be employed to tune the final material properties as per the need of the application under investigation. Finally, the deprotonation of diols with sodium hydride followed by alkylation with 2 equivalents of propargyl bromide yielded the respective dipropargyl ethers, 2c and 2d, with high overall yields of 66% and 76%, respectively. Both 2c and 2d monomers were obtained as liquids with viscosity values of 171 cP and 732 cP, respectively, in addition to refractive index values (nD/20° C.) of 1.603 and 1.668, respectively. Overall, the synthesis of these intermediates for both multifunctional thiols and diyne monomers is easily scaled up and stored for several months without any special precautions to be considered.

### Examples

Various embodiments of the present application can be better understood by reference to the following Examples which are offered by way of illustration. The scope of the present application is not limited to the Examples given herein.

General information for chemical synthesis: Commercially available reagents were used without further purification. Thiophenol, epichlorohydrin, 2-mercapthoethanol and ethane dithiol were purchased from Alfa Aesar. 1,8-Diazabicyclo[5.4.0]undec-7-ene (DBU) was purchased from Chem-Impex International. Diphenyl(2,4,6-trimethylbenzoyl)phosphine oxide (TPO) photoinitiator was purchased from TCI America. Thiourea was purchased from Sigma-Aldrich. Reagent-grade sodium hydroxide (NaOH) was purchased from Fisher Scientific. Absolute ethanol (200 proof) was purchased from Decon Labs Inc. ¹H and ¹³C-NMR spectra were recorded in CDCl₃ (internal standard: 7.26 ppm, ¹H; 77.0 ppm, ¹³C) on a Bruker 400 MHz spectrometer.

### Example 1: Preparation of 1,3-bis(2-mercaptoethylthio)-2-mercaptopropane (BMEMP, 1b)

1,3-bis(2-mercaptoethylthio)-2-mercaptopropane (BMEMP\): To a dry 500 g round-bottomed flask equipped with a magnetic stir bar was added 17.8 g of 2-mercaptoethanol (228 mmol, 2.08 equiv.) and was diluted with 69 mL (1.58 M) of absolute ethanol and homogenized. To this solution, 9.13 g (228 mmol, 2.09 equiv.) of sodium hydroxide was added. After stirring at room temperature for 10 min, 10.1 g (109 mmol, 1 equiv.) of epichlorohydrin was added slowly to the reaction mixture under N₂ atmosphere. The mixture was heated to 50° C. and stirred for 1 hr. After this period, the reaction mixture was cooled to room temperature and 13.5 g of 36% hydrochloric acid (133 mmol, 1.22 equiv.) was added to form a precipitate.

The precipitate was filtered and concentrated under reduced pressure to yield 22.05 g (95%) of 1,3-bis(2-hydroxyethylthio)-2-propanol (BHETP) as a slightly yellow, viscous liquid which was used directly in the next step without further purification. In second step, to a dry 500 g round-bottomed flask equipped with a reflux condenser and magnetic stir bar was added 22 g of BHETP (104 mmol, 1 equiv.) and 28.9 g (379 mmol, 3.66 equiv.) of thiourea, and was dissolved in 63.3 g (1.58 M) of 36% aqueous hydrochloric acid solution and homogenized. This solution was heated to 110° C. and stirred for 1 hr. After this period, the reaction was cooled to room temperature and 61.5 g (762 mmol, 7.35 equiv.) of 50% aqueous NaOH solution was added under N₂ atmosphere. The suspension was then allowed to stir at room temperature for 24 hr. After this period, 200 mL of toluene was added and the mixture was filtered via suction then transferred to a separatory funnel. The organic layer was washed with 1 M hydrochloric acid solution, water and brine then dried over sodium sulfate. The solution was filtered and concentrated under reduced pressure to yield 25.2 g (93%) of the title compound as a colorless liquid which was used as is without further purification. BHETP: ¹H NMR (400 MHz, CDCl₃) δ=5.05 (d, 1H), 4.77 (t, 2H), 3.72-3.67 (m, 1H), 3.55-3.50 (m, 4H), 2.70-0.55 (m, 8H); ¹³C NMR (101 MHz, CDCl₃) δ=70.9, 61.4, 38.2, 35.2.

BMEMP: ¹H NMR (400 MHz, CDCl₃) δ=2.95-2.71 (m, 15H), 1.79-1.72 (m, 3H); ¹³C NMR (101 MHz, CDCl₃) δ=49.0, 37.2, 36.2, 35.8, 28.8, 25.1, 24.9.

### Example 1a: Alternative preparation of 1,3-bis(2-mercaptoethylthio)-2-mercaptopropane (BMEMP, 1b)

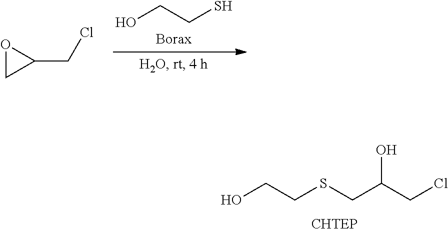

1-chloro-3-(hydroxyethylthio)-2-propanol (CHTEP)²: To a 500 mL round-bottomed flask equipped with a magnetic stir bar was added 21.2 mL (25.0 g, 0.27 mol, 1 equiv.) of epichlorohydrin and 10.3 g (0.027 mol, 0.1 equiv.) of borax and diluted with 135 mL of deionized water. To this suspension, 19 mL (21.1 g, 0.27 mol, 1 equiv.) of 2-mercaptoethanol was added dropwise over a period of 1 h using an addition funnel. The reaction was allowed to stir at room temperature for 4 h. After this period, the mixture was extracted with CH₂Cl₂ (3×100 mL). The combined organics were washed with water (˜100 mL, 2λ), brine (˜50 mL, 1λ), dried over Na₂SO₄, filtered and evaporated under reduced pressure to yield 43.0 g (93%) of the title compound CHTEP as colorless viscous liquid which was used directly in the next step with no further purifications. ¹H NMR (400 MHz, CDCl₃) δ=3.99-3.95 (m, 1H), 3.81-3.77 (m, 2H), 3.69-3.61 (m, 2H), 2.87-2.68 (m, 4H); ¹³C NMR (101 MHz, CDCl₃) δ=70.7, 61.3, 48.0, 36.4, 36.1.

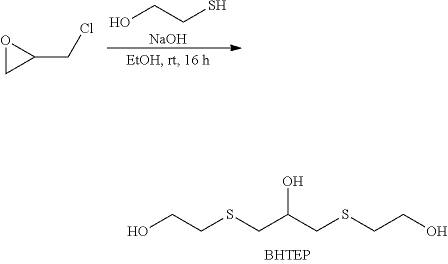

1,3-bis-(hydroxyethylthio)-2-propanol (BHETP): The synthesis of BHETP was adapted from a procedure reported in the patent literature.² To a 1 L round-bottomed flask equipped with a magnetic stir bar was added 33.6 mL (37.2 g, 0.48 mol, 2.1 equiv.) of 2-mercaptoethanol and was diluted with 318 mL of reagent grade ethanol. To this solution, 19.0 g (0.48 mmol, 2.1 equiv.) of NaOH was added. After stirring at room temperature for 10 min, 21.0 g (0.23 mol, 1.0 equiv.) of epichlorohydrin was added slowly under N₂ atmosphere. The resulting suspension was stirred at room temperature for 16 h. After this period, 27.5 g (0.27 mol, 1.2 equiv.) of 36% hydrochloric acid was added. The precipitate was filtered, and concentrated under reduced pressure to yield 46.7 g (97%) of the title compound BHETP as colorless viscous liquid which was used directly in the next step with no further purifications. H NMR (400 MHz, CDCl₃) δ=5.05 (d, 1H), 4.77 (t, 2H), 3.72-3.67 (m, 1H), 3.55-3.50 (m, 4H), 2.70-0.55 (m, 8H); ¹³C NMR (101 MHz, CDCl₃) δ=70.9, 61.4, 38.2, 35.2.

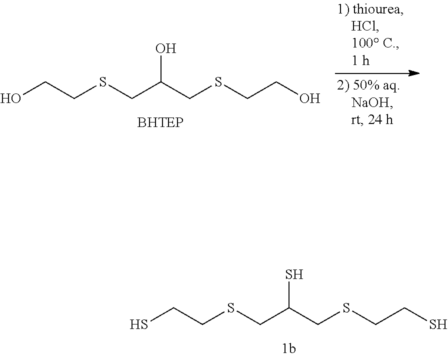 [SMILES: OCCSCC(O)CSCCO ; SCCSCC(S)CSCCS]

1,3-bis(2-mercaptoethylthio)-2-mercaptopropane (1b): To a 1 L round bottomed flask equipped with a reflux condenser and stir bar, was added 46.7 g (0.22 mol, 1 equiv.) of BHETP, and was dissolved in 133.7 g (1.32 mol, 6 equiv.) of 36% aqueous hydrochloric acid solution. To this solution, 75.3 g (0.99 mol) of thiourea was added and heated to 110° C. for 1 h. After this period, the flask was cooled to room temperature and 132.0 g (1.65 mol, 7.5 equiv.) of 50% aqueous NaOH solution was added under N₂ atmosphere. The suspension was then allowed to stir at room temperature for 24 h. After this period, 200 mL of toluene was added and the mixture was transferred to a separatory funnel, washed with 1M hydrochloric acid solution (150 mL, 1λ), water (˜100 mL, 1λ), brine (50 mL, 1λ), dried over Na₂SO₄, filtered, and evaporated under reduced pressure to yield the title compound 1b as a colorless viscous liquid which was used with no further purifications. ¹H NMR (400 MHz, CDCl₃) δ=2.95-2.71 (m, 15H), 1.79-1.72 (m, 3H); ¹³C NMR (101 MHz, CDCl₃) δ=49.0, 37.2, 36.2, 35.8, 28.8, 25.1, 24.9. HRMS (ESI): calculated [M+Cl]⁻ for C₇H₁₆S₅Cl: 295.9544, found: 295.9549.

### Example 1b: Preparation of TetraOH

TetraOH: To a 500 mL round-bottomed flask equipped with a magnetic stir bar was added 4.46 mL (5.00 g, 0.053 mol, 1 equiv.) of 1,2-ethanedithiol and was diluted with 106 mL of ethanol. To this solution, 4.24 g (0.106 mol, 2 equiv.) of NaOH was added. After stirring at room temperature for 10 min, 18.1 g (0.106 mol, 2 equiv.) of CHTEP was added slowly under N₂ atmosphere. The resulting suspension was allowed to stir at room temperature for 16 h. After this period, 12.9 g 0.127 mol, 2.4 equiv.) of 36% hydrochloric acid was added and the precipitated solid was filtered off. The filtrate was evaporated under reduced pressure to yield 18.1 g (94%) of the title compound as colorless viscous liquid which was used directly in the next step with no further purifications. ¹H NMR (400 MHz, DMSO-d6) δ=4.78 (bs, 4H), 3.73-3.67 (m, 2H), 3.35 (t, 4H), 2.74-2.54 (m, 6H); ¹³C NMR (101 MHz, DMSO-d6) δ=70.4, 60.91, 37.7, 37.2, 34.8, 32.3.

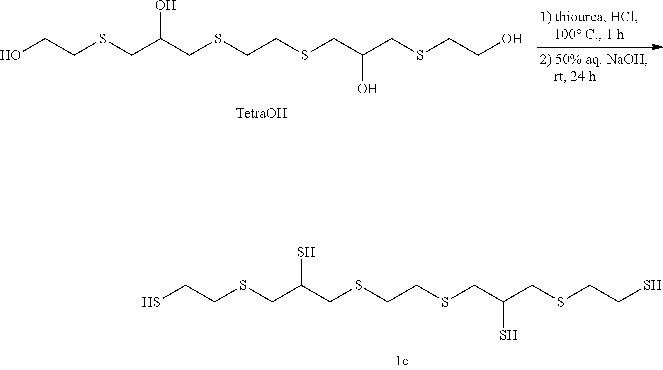 [SMILES: OCCSCC(O)CSCCSCC(O)CSCCO ; SCCSCC(S)CSCCSCC(S)CSCCS]

### Example 1c: Preparation of Monomer 1c

1c: To a 500 mL round bottomed flask equipped with a reflux condenser and stir bar, was added 18 g (0.049 mol, 1 equiv.) of TetraOH, and was dissolved in 40.2 g (0.397 mol, 8 equiv.) of 36% aqueous hydrochloric acid solution. To this solution, 18.1 g (0.238 mol, 4.8 equiv.) of thiourea was added and heated to 110° C. for 1 h. After this period, the flask was cooled to room temperature and 19.9 g (0.496 mol, 10 equiv.) of 50% aqueous NaOH solution was added under N₂ atmosphere. The suspension was then allowed to stir at room temperature for 24 h. After this period, 500 mLs of toluene was added and the mixture was transferred to a separatory funnel, washed with 1M hydrochloric acid solution (250 mLs, 1×), water (˜150 mLs, 1×), brine (100 mLs, 1×), dried over Na₂SO₄, filtered, and evaporated under reduced pressure to yield 16.2 g (76%) of the title compound 1c as colorless viscous liquid which was used with no further purifications. ¹H NMR (400 MHz, CDCl₃) δ=2.96-2.69 (m, 22H); ¹³C NMR (101 MHz, DMSO-d6) δ=51.6, 48.9, 37.1, 36.1, 35.7, 28.8, 28.7, 28.2, 25.1, 24.9; HRMS (ESI): calculated [M+Li]⁺ for C₁₂H₂₆S₈Li: 432.9960, found: 432.9990.

### Example 1d: Preparation of 1,3-Bis-(phenylthio)-2-propanol (BPTP)

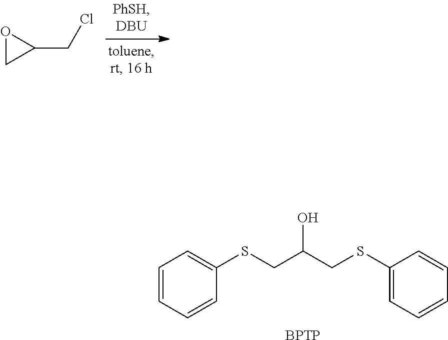

1,3-Bis-(phenylthio)-2-propanol (BPTP): To a 250 mL round-bottomed flask equipped with a magnetic stir bar was added 16 mL (157 mmol, 2.2 equiv) of thiophenol and then diluted with 230 mL of toluene (0.3 M, w.r.t. epichlorohydrin). To this solution, 23 mL of DBU (154 mmol, 2.2 equiv) was added under N₂ atmosphere and stirred at room temperature for 10 min. After this period, 5.5 mL of epichlorohydrin (70.3 mmol, 1.0 equiv.) was added dropwise and the reaction vessel was allowed to stir at room temperature for 16 h. After this period, the volatiles were removed under reduced pressure. The residue was diluted with 500 mL DCM and washed with 1M HCl (100 mL), water (100 mL), brine (50 mL) and dried over anhydrous Na₂SO₄, filtered, and concentrated under reduced pressure to yield the crude product as pale yellow liquid. was purified by silica-gel column chromatography using 50% EtOAc in hexane as an eluent to yield BPTP (17.1 g, 88% yield) as colorless, viscous liquid. ¹H NMR (400 MHz, Chloroform-d): δ 7.36-7.33 (m, 4H), 7.29-7.24 (m, 4H), 7.22-7.18 (m, 2H), 3.86-3.79 (m, 1H), 3.20 (dd, J=13.8, 5.0 Hz, 2H), 3.05 (dd, J=13.8, 7.2 Hz, 2H), 2.74 (d, 1H). ¹³C NMR (101 MHz, Chloroform-d, 25° C.): δ 135.1, 129.9, 129.1, 126.7, 68.2, 40.1.

### Example 1e: Preparation of 1-chloro-3-(phenylthio)-2-propanol (CPTP)

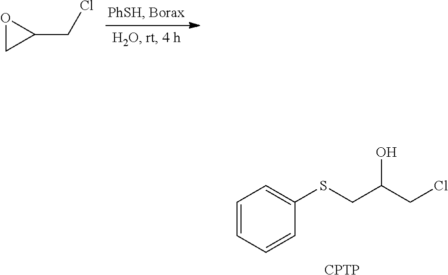

1-chloro-3-(phenylthio)-2-propanol (CPTP): To a 500 mL round-bottomed flask equipped with a magnetic stir bar was added 50.0 mL (0.64 mol, 1 equiv.) of epichlorohydrin and 24.4 g (0.064 mol, 0.1 equiv.) of borax and diluted with 320 mL of deionized water. To this suspension, 65 mL (0.64 mol, 1 equiv.) of thiophenol was added dropwise over a period of 1 h using an addition funnel. The reaction was allowed to stir at room temperature for 4 h. After this period, the mixture was extracted with CH₂Cl₂ (3×100 mL). The combined organic extracts were washed with water (˜100 mL, 2×), brine (˜50 mL, 1×), dried over Na₂SO₄, filtered and evaporated under reduced pressure to yield 99.3 g (96%) of the title compound CPTP as colorless liquid which was used directly in the next step with no further purifications. ¹H NMR (400 MHz, CDCl₃) δ=7.42-7.39 (m, 2H), 7.33-7.29 (m, 2H), 7.26-7.22 (m, 1H), 3.97-3.90 (m, 1H), 3.72-3.64 (m, 2H), 3.20-3.06 (m, 2H), 2.62 (d, 1H); ¹³C NMR (101 MHz, CDCl₃) δ=134.7, 130.3, 130.1, 129.4, 127.1, 69.7, 48.1, 38.4.

### Example 1f: Alternative Preparation of 1,2-Ethanedithiol-Based Intermediate Diol (EDTOH)

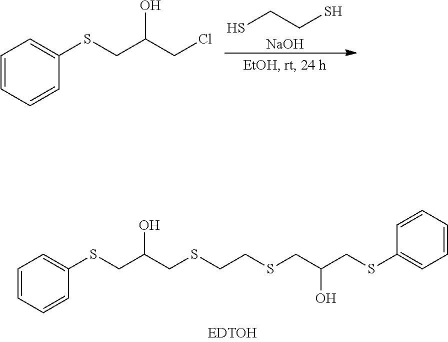

1,2-ethanedithiol-based intermediate diol (EDTOH): To a 500 mL round-bottomed flask equipped with a magnetic stir bar was added 4.46 mL (5.00 g, 53.08 mmol, 1 equiv.) of 1,2-ethanedithiol and was diluted with 106 mL of ethanol. To this solution, 4.25 g (106.16 mmol, 2 equiv.) of NaOH was added. After stirring at room temperature for 10 min, 21.5 g (106.16 mmol, 2 equiv.) of CPTP was added slowly under N₂ atmosphere. The resulting suspension was stirred at room temperature for 24 h. After this period, the ethanol was removed under reduced pressure to afford a crude residue which was diluted with EtOAc (˜500 mL), washed with 1N HCl (˜150 mL, 2×), water (˜150 mL, 1×), and brine (˜150 mL, 1×). The combined organics were dried over Na₂SO₄, filtered, and concentrated under reduced pressure to yield yellow viscous liquid which was submitted to silica-gel column chromatography using 60% EtOAc/Hex as eluent. Evaporation of the fractions containing the desired material yielded 22.1 g (97%) of the title compound EDTOH as colorless viscous liquid. ¹H NMR (400 MHz, CDCl₃) δ=7.40-7.37 (m, 4H), 7.31-7.26 (m, 4H), 7.23-7.19 (m, 2H), 3.84-3.78 (m, 2H), 3.16-3.11 (m, 2H), 3.06-3.01 (m, 2H), 2.84-2.78 (m, 2H), 2.74 (m, 4H), 2.68-2.62 (m, 2H); ¹³C NMR (101 MHz, CDCl₃) δ=135.2, 130.1, 129.3, 126.8, 69.1, 40.3, 38.2, 32.9.

### Example 1g: Preparation of 4,4′-Thiobisbenzenethiol-Based Intermediate Diol (TBTOH)

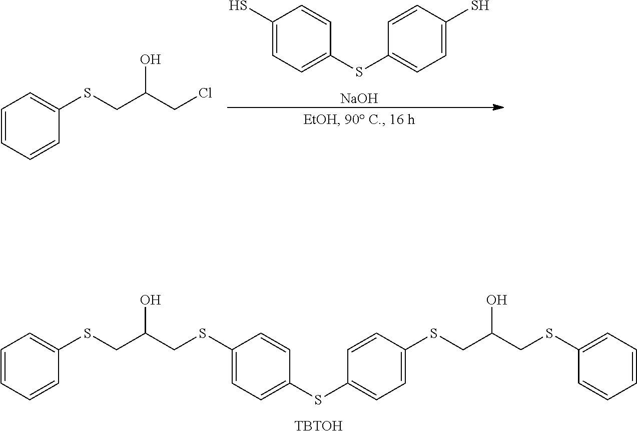

4,4′-thiobisbenzenethiol-based intermediate diol (TBTOH): To a 500 mL round-bottomed flask equipped with a magnetic stir bar was added 5.00 g (19.97 mmol) of 4,4′-thiobenzenethiol and was diluted with 200 mL of toluene. To this suspension, 6.08 g (39.93 mmol, 2 equiv.) of DBU (1,8-diazabicyclo[5.4.0]undec-7-ene) was added. After stirring at room temperature for 10 min, 8.09 g (39.93 mmol, 2 equiv.) of CPTP was added slowly under N₂ atmosphere. The resulting suspension was heated to 90° C. for 16 h. After this period, the reaction was cooled to room temperature and toluene was removed under reduced pressure to afford a crude residue which was diluted with EtOAc (˜250 mLs), washed with 1N HCl (˜100 mL, 2×), water (˜100 mL, 1×), and brine (˜50 mL, 1×). The combined organics were dried over Na₂SO₄, filtered, and concentrated under reduced pressure to yield yellow viscous liquid which was submitted to silica-gel column chromatography using 60% EtOAc/Hex as eluent. Evaporation of the fractions containing the desired material yielded 10.6 g (91%) of the title compound TBTOH as pale yellow viscous liquid. ¹H NMR (400 MHz, CDCl₃) δ=7.38-7.35 (m, 4H), 7.31-7.26 (m, 8H), 7.24-7.19 (m, 6H), 3.88-3.83 (m, 2H), 3.24-3.19 (m, 4H), 3.10-3.04 (m, 4H), 2.80 (bs, 2H)); ¹³C NMR (101 MHz, CDCl₃) δ=135.0, 134.7, 133.9, 131.6, 130.4, 130.1, 129.3, 126.9, 68.2, 40.2, 39.9.

### Example 1h: Preparation of 1,3-bis-(n-propylthio)-2-propanol (BPrTP)

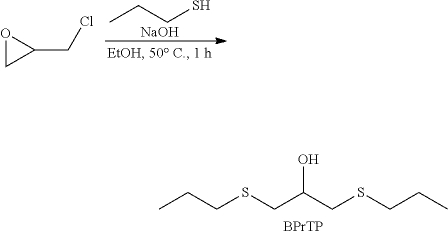

1,3-bis-(n-propylthio)-2-propanol (BPrTP): To a 250 mL round-bottomed flask equipped with a magnetic stir bar was added 7.8 mL (8.6 g, 113.5 mmol, 2.1 equiv.) of n-propylthiol and was diluted with 75 mL of reagent grade ethanol. To this solution, 4.54 g (113.5 mmol, 2.1 equiv.) of NaOH was added. After stirring at room temperature for 10 min, 5.0 g (54.0 mmol, 1.0 equiv.) of epichlorohydrin was added slowly under N₂ atmosphere. The resulting suspension was heated to 50° C. for 1 h. After this period, the flask was cooled to room temperature and 6.4 g (64.8 mmol, 1.2 equiv.) of 36% hydrochloric acid was added. The precipitate was filtered, and concentrated under reduced pressure to yield 10.2 g (91%) of the title compound as colorless liquid which was used directly in the next step with no further purifications. ¹H NMR (400 MHz, Chloroform-d) δ 3.82-3.76 (m, 1H), 2.76 (dd, J=13.6, 4.7 Hz, 2H), 2.62 (dd, J=13.6, 7.5 Hz, 2H), 2.53 (dd, J=7.7, 7.0 Hz, 4H), 1.64-1.57 (m, 4H), 0.98 (t, J=7.3 Hz, 6H); ¹³C NMR (101 MHz, CDCl₃) δ=68.8, 38.4, 34.8, 23.2, 13.6.

### Example 1i: Preparation of 1,3-bis-(n-propylthio)-2-propanethiol (3a)

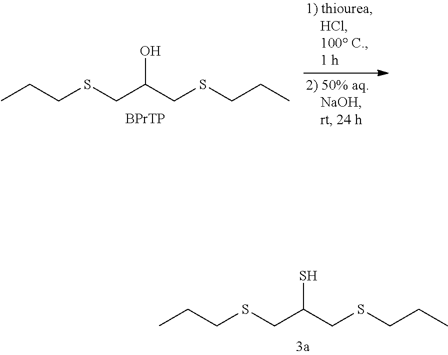

1,3-bis-(n-propylthio)-2-propanethiol (3a): To a 250 mL round bottomed flask equipped with a reflux condenser and stir bar, was added 10.2 g (48.95 mmol, 1 equiv.) of BPrTP, and was dissolved in 9.9 g (97.9 mmol, 2 equiv.) of 36% aqueous hydrochloric acid solution. To this solution, 5.6 g (73.42 mmol, 1.5 equiv.) of thiourea was added and heated to 110° C. for 1 h. After this period, the flask was cooled to room temperature and 9.8 g (122.4 mmol, 2.5 equiv.) of 50% aqueous NaOH solution was added under N₂ atmosphere. The suspension was then allowed to stir at room temperature for 24 h. After this period, 200 mL of toluene was added and the mixture was transferred to a separatory funnel, washed with 1M hydrochloric acid solution (150 mL, 1×), water (˜100 mL, 1×), brine (50 mL, 1×), dried over Na₂SO₄, filtered, and evaporated under reduced pressure to yield the crude product which was purified by silica-gel column chromatography using 10% EtOAc/hexanes as eluent to yield 8.4 g (77%) of the title compound 3a as colorless liquid. ¹H NMR (400 MHz, Chloroform-d) δ 2.95-2.81 (m, 4H), 2.56-2.51 (m, 4H), 1.80 (t, J=8.1 Hz, 1H), 1.65-1.58 (m, 4H), 1.02-0.97 (m, 6H); ¹³C NMR (101 MHz, CDCl₃) δ=48.3, 39.8, 36.1, 35.1, 33.5, 28.5, 23.3, 23.2, 13.7, 13.6.

### Example 2: Preparation of 1,2-ethanedithiol-Based Diallyl Ether (EDTDAE)

1,2-ethanedithiol-based diallyl ether (EDTDAE): EDTDAE was prepared according to a previously reported procedure. Briefly, to a dry 500 g round-bottomed flask equipped with a magnetic stir bar was added 50 mL (640 mmol, 1 equiv.) of epichlorohydrin and 24.4 g (64 mmol, 0.1 equiv.) of borax to 320 mL (2 M) of deionized water. 65 mL (635 mmol, 1 equiv.) of thiophenol was added dropwise to the stirring solution using an addition funnel over 1 hour. The reaction was allowed to proceed at room temperature for 4 hours. Subsequently the mixture was extracted with CH₂Cl₂ (3×100 mL) then washed with water (200 mL) and brine (50 mL). The combined extracts were dried with Na₂SO₄ and concentrated in vacuo to obtain 99.3 g of 1-chloro-3-(phenylthio)-2-propanol (CPTP) (96% yield). No further purification was performed and the compound was used as is. In second step, to a 500 mL round-bottomed flask equipped with a magnetic stir bar was added 4.46 mL (5.00 g, 53.08 mmol, 1 equiv.) of 1,2-ethanedithiol and was diluted with 106 mL of ethanol. To this solution, 4.25 g (106.16 mmol, 2 equiv.) of NaOH was added. After stirring at room temperature for 10 min, 21.5 g (106.16 mmol, 2 equiv.) of CPTP was added slowly under N₂ atmosphere.

The resulting suspension was stirred at room temperature for 24 h. After this period, the ethanol was removed under reduced pressure to afford a crude residue which was diluted with EtOAc (˜500 mL), washed with 1N HCl (˜150 mL, 2×), water (˜150 mL, 1×), and brine (˜150 mL, 1×). The combined organics were dried over Na₂SO₄, filtered, and concentrated under reduced pressure to yield yellow viscous liquid which was submitted to silica-gel column chromatography using 60% EtOAc/Hexanes as eluent. Evaporation of the fractions containing the desired material yielded 22.1 g (97%) of 1,2-ethanedithiol-based diol (EDT-OH) as a colorless viscous liquid. In last step, to a 500 mL round-bottomed flask equipped with a magnetic stir bar was added 10.0 g (23.44 mmol, 1 equiv.) of EDT-OH and was diluted with 117 mL of anhydrous THF. The flask was cooled to 0° C. and 1.69 g (70.31 mmol, 3 equiv.) of NaH was added in portions. After stirring at room temperature for 30 min, 8.50 g (70.31 mmol, 3 equiv.) of allyl bromide was added followed by 0.39 g (2.34 mmol, 0.1 equiv.) of potassium iodide. The resulting solution was stirred at room temperature for 16 h. After this period, the reaction mixture was diluted with EtOAc (˜300 mL), washed with 1N HCl (˜100 mL, 2×), water (˜100 mL, 1×), and brine (˜50 mL, 1×). The combined organics were dried over Na₂SO₄, filtered, and concentrated under reduced pressure to yield the crude as pale yellow liquid which was purified by silica-gel column chromatography eluting with (30% EtOAc/hexanes). Evaporation of the fractions containing the product under reduced pressure yielded 8.3 g (71%) of the title compound (EDTDAE) as a pale yellow viscous liquid. CPTP: ¹H NMR (400 MHz, CDCl₃) δ=7.42-7.39 (m, 2H), 7.33-7.29 (m, 2H), 7.26-7.22 (m, 1H), 3.97-3.90 (m, 1H), 3.72-3.64 (m, 2H), 3.20-3.06 (m, 2H), 2.62 (d, 1H); ¹³C NMR (101 MHz, CDCl₃) δ=134.7, 130.3, 130.1, 129.4, 127.1, 69.7, 48.1, 38.4.

EDT-OH: ¹H NMR (400 MHz, CDCl₃) δ=7.40-7.37 (m, 4H), 7.31-7.26 (m, 4H), 7.23-7.19 (m, 2H), 3.84-3.78 (m, 2H), 3.16-3.11 (m, 2H), 3.06-3.01 (m, 2H), 2.84-2.78 (m, 2H), 2.74 (m, 4H), 2.68-2.62 (m, 2H); ¹³C NMR (101 MHz, CDCl₃) δ=135.2, 130.1, 129.3, 126.8, 69.1, 40.3, 38.2, 32.9.

EDTDAE: ¹H NMR (400 MHz, CDCl₃) δ=7.39-7.36 (m, 4H), 7.31-7.26 (m, 4H), 7.21-7.17 (m, 2H), 5.99-5.83 (m, 2H), 5.25-5.13 (m, 4H), 4.09-4.00 (m, 4H), 3.67-3.61 (m, 2H), 3.18-3.16 (m, 4H), 2.87-2.73 (m, 8H); ¹³C NMR (101 MHz, CDCl₃) δ=136.2, 134.7, 129.6, 129.1, 126.4, 117.6, 77.8, 71.2, 37.0, 35.6, 33.2, 33.1.

### Example 3: Films for Hologram Recording

Preparation of films for hologram recording: polycaprolactone-block-polytetrahydrofuran-block-polycaprolactone (Mₙ˜2000), 1,6-diisocyanatohexane and 2-(Allyloxymethyl)-2-ethyl-1,3-propanediol were mixed together in vials according to Table 3 to obtain linear polyurethane with various content of allyl side chain.

TABLE 3
Compositional table of linear matrices.

| Allyl Content^{a} | 0 mol % | 10 mol % | 30 mol % | 50 mol % |
|---|---|---|---|---|
| Mass of TMPAE (g) | 0.000 | 0.017 | 0.052 | 0.086 |
| Mass of Polyol 2000 (g) | 2.000 | 1.800 | 1.400 | 1.000 |
| Mass of HDI (g) | 0.1682 | 0.1682 | 0.1682 | 0.1682 |

^{a}Allyl content = Moles of TMPAE/(Moles of TMPAE + Moles of polyol 2000). HDI = 1,6-hexane diisocyanate.

Then, vials were placed in oven at 70° C. overnight for polymerization. After that, acetone was used as solvent to prepare polymer solutions whose concentration were controlled at 20% w/w (determined by mass of polymer binder relative to sum of polymer and solvent); meanwhile, thiol-ene writing monomers were also dissolved in the solution using stoichiometry ratio, which can be found in Table 4.

TABLE 4
Compositional table of writing monomers.^{a}

| Thiol-ene Content | 20 w % | 33 w % | 43 w % |
|---|---|---|---|
| Mass of Thiol (g) | 0.0125 | 0.025 | 0.0375 |
| Mass of ene (g) | 0.0375 | 0.075 | 0.1125 |
| Mass of thiol-ene (g) | 0.05 | 0.1 | 0.15 |
| Mass of TPO (mg) | 1.5 | 3.0 | 4.5 |

^{a}Thiol-ene content = Mass of thiol-ene monomers/(Mass of polymer
matrix + Mass of thiol-ene) 100 μL solution was blade coated for each film on one glass slide (Fisherbrand 2.54 cm × 7.62 cm), during which ZAA 2300 Automatic Film Applicator was used when temperature maintained at 45° C. Finally, films were kept on the platform at 45° C. for 2 minutes.

The refractive indices of linear matrices with various allyl content, according to various embodiments, are summarized in Table 5.

TABLE 5
Refractive indices of linear matrices
with various amounts of allyl content.

| Allyl Content | 0 mol % | 10 mol % | 30 mol % | 50 mol % |
|---|---|---|---|---|
| n_{f} (486.2 nm)^{a} | 1.480 ± | 1.481 ± | 1.482 ± | 1.485 ± |
| | (3 × 10⁻⁴) | (3 × 10⁻⁴) | (6 × 10⁻⁴) | (6 × 10⁻⁴) |
| n_{d} (589.3 nm)^{a} | 1.474 ± | 1.475 ± | 1.476 ± | 1.478 ± |
| | (6 × 10⁻⁴) | (5 × 10⁻⁴) | (1 × 10⁻⁴) | (5 × 10⁻⁴) |
| n_{c} (657.4 nm)^{a} | 1.471 ± | 1.473 ± | 1.473 ± | 1.476 ± |
| | (4 × 10⁻⁴) | (9 × 10⁻⁴) | (8 × 10⁻⁴) | (6 × 10⁻⁴) |
| Abbe Number^{b} | 56.4 | 57.2 | 54.8 | 55.6 |

^{a}All refractive indices are averaged from three samples.
^{b}Abbe number = (n_{d} − 1)/(n_{f} − n_{c})

Molecular weights of linear polymer matrices, according to some embodiments, are listed in Table 6.

TABLE 6
Molecule weight of linear polymer matrices.^{a}

| Allyl Content | 0 mol % | 10 mol % | 30 mol % | 50 mol % |
|---|---|---|---|---|
| Mₙ | 1.7 × 10⁴ | 1.5 × 10⁴ | 1.8 × 10⁴ | 1.7 × 10⁴ |
| M_{w} | 2.2 × 10⁴ | 1.7 × 10⁴ | 2.5 × 10⁴ | 2.3 × 10⁴ |
| PDI | 1.3 | 1.1 | 1.4 | 1.4 |

^{a}Molecular weights were measured twice and the average of two tests were used. PDI was calculated using average molecular weights.

### Example 4: Properties of Recorded Holograms

Holographic recording and dynamic range (Δn) determination: Transmission hologram was recorded in a two-beam interference setup shown in FIG. 11. A spatial filtered wavelength-stabilized 405 nm laser diode (Ondax, 40 mW) was used to generate power-matched recording beams with a total intensity of ˜16 mW/cm². Two grating periods, 0.5 μm and 1 μm, were used in the experiments, which were realized by recording at an external recording half-angle of 23.9° and 11.2° respectively. Besides, hologram developments during the recording process were probed simultaneously via a 633 nm He—Ne laser (Thorlabs) aligned approximately at Bragg reconstruction angle. After writing, a sample rotation from −150 to 15° at a speed of 0.2°/s was applied to obtain the angular selectivity of the hologram recorded; diffraction efficiency (DE), defined as quotient of diffracted power to the total power (transmitted and diffracted), was recorded versus time during this rotation. A 15 s exposure was used for groups with monomer loading of 33 w % and 43 w %, while 20 w % groups was exposed for 45 s; therefore, best diffraction efficiency was achieved in every sample. Lastly, Kogelnik coupled wave theory was applied to fit angular selectivity to obtain refractive index modulation (Δn) and film thickness.

Determination of film profile: Surface roughness and thickness measurement of films were conducted using XT-model stylus profilometer from Dektak. Thickness was obtained via scanning from empty area of glass substrate to the area covered with polymer film. Scanning within film areas was used to analyze film roughness.

Shelf life evaluation of writing monomers: Trithiol and diene monomers were mixed at stoichiometric ratio in a vial; 3 w % photoinitiator, diphenyl(2,4,6-trimethylbenzoyl)phosphine oxide (TPO), was added according to the mass of monomers and homogenized using Vortex mixer. Then the mixture was cast onto a clean glass slide (Fisher Scientific) and sandwiched with the same slide using binder clip with 250 μm thick polyethylene terephthalate spacers. A Thermo Scientific Nicolet iS50 FT-IR spectrometer was used in near IR range to monitor the double bond remained over time by calculating ratio between areas of double bond peak (˜6113 cm⁻¹) and that of all peaks (5570 cm⁻¹-6180 cm⁻¹). The percentage of double bond remained was obtained by comparing the ratio after different time with the initial ratio.

Stability evaluation of holograms and non-recorded films: There were three stabilities evaluated in this experiment. Empty film (EF) stability was determined using ratio between dynamic ranges of holograms recorded at specific time after film preparation and that right after film preparation. Dynamic ranges obtained from reading of same holograms at various time were compared to initial dynamic range to reveal stability of hologram-recorded film (HF) and flood-cured hologram film (FCHF). Flood curing was conducted by exposing samples to a 27 W 405 nm LED lamp for 3 mins.

Haze Measurement of Holograms and Films: Transmission Haze percentage was measured using haze meter named Haze-gard i from BYK whose measuring area of 18 mm². Three samples were prepared for each formulation, while each sample was measured three times at different spots. Therefore, average with standard deviation was obtained and plotted in figures.

Microscopic Characterization of Grating in Holograms: Dimensional 3100 Atomic Force Microscope (AFM) made by Digital Instruments was applied to obtain height profile within holograms with a scanning size of 10 μm at scanning rate of 0.5003 Hz. Hitachi SU3500 Scanning Electron Microscope (SEM) of hologram was analyzed by Hitachi SU3500 SEM

Refractive Index (RI) Measurement: Refractometer from Anton Paar was used to determine the refractive indices at the wavelengths of the Fraunhofer C, D, and F spectral lines (656.3 nm, 589.3 nm, and 486.1 nm respectively). Then Abbe numbers could be calculated according to definition. Refractive indices of writing monomers and linear polymer matrices were measured directly. Thiol-ene writing monomers were mixed at stoichiometry with 3% w/w % TPO and exposed to 405 nm LED lamp for 3 mins to form polymer. After that, the polymer' RI was measured to represent the RI of writing polymer formed in bright fringes during recording.

Reflection hologram recording: The films used for reflection holography were prepared using blade coating multiple times obtain thick films around 25 μm. Reflection holograms were recorded in a single-beam Denisyuk configuration with the laser intensity of 131 mW/cm² at incident angle of 100 (FIG. 4A), following a flood-curing process under 405 nm LED for 3 mins; then transmission spectra were measured at same spot of recording with a high-resolution spectrometer (Avantes AvaSpec-ULS4096CL-EVO).

The terms and expressions employed herein are used as terms of description and not of limitation, and there is no intention in the use of such terms and expressions of excluding any equivalents of the features shown and described or portions thereof, but it is recognized that various modifications are possible within the scope of the embodiments of the present application. Thus, it should be understood that although the present application describes specific embodiments and optional features, modification and variation of the compositions, methods, and concepts herein disclosed may be resorted to by those of ordinary skill in the art, and that such modifications and variations are considered to be within the scope of embodiments of the present application.

### Example 5: Photopolymerization and Real Time FTIR Kinetics of Thiol-yne Monomers

Without being bound by theory, a generally accepted mechanism of the thiol-yne photopolymerization is shown in Scheme 2. Mechanistically, the radical mediated thiol-yne reaction is analogous to that of the radical-mediated thiol-ene reaction in which each alkyne groups react twice with thiyl radicals. The additional step involves the reaction of a vinyl sulfide intermediate formed in the first step with a second thiyl radical followed by a chain transfer to thiol to form another sulfide linkage. In kinetic analysis, each terminal alkyne group is considered difunctional and therefore to produce network polymers a minimum of two functionalities are required for both thiol and alkyne monomers.

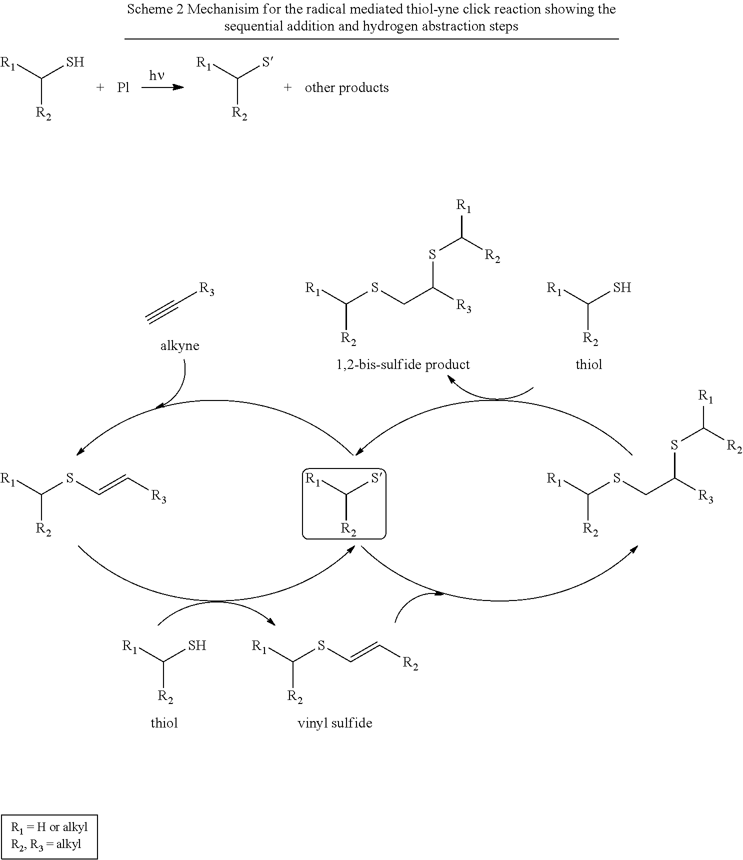

TABLE 7
Physical and optical properties of thiol-yne based photophotopolymer networks.
Thiol-yne resins were formulated by mixing thiol and alkyne monomers in a 2:1 molar
ratio of thiol:yne functional groups with ~1 wt % 2,4,6-trimethylbenzoyl
diphenyl phosphine oxide (TPO) and were photopolymerized by irradiating
with 405 nm LED light at 30 mW/cm².

| Fomu- | | | | n_{D} (589 nm)^{b} | n_{D polymer}- | |
|---|---|---|---|---|---|---|
| lation | Thiol | Yne | η(cP)^{a} | polymer (resin) | n_{D resin} | T_{g} ° C. |
| A1 | 1a | 2a | 13 | 1.645 (1.606) | 0.039 | −33.8^{c} |
| A2 | ″ | 2b | 7 | 1.676 (1.596) | 0.080 | 0 |
| A3 | ″ | 2c | 28 | 1.644 (1.601) | 0.043 | −18.0 |
| A4 | ″ | 2d | 71 | 1.669 (1.637) | 0.032 | −3.8 |
| B1 | 1b | 2a | 26 | 1.649 (1.618) | 0.031 | −39.4^{c} |
| B2 | ″ | 2b | 20 | 1.682 (1.605) | 0.077 | 19.2 |
| B3 | ″ | 2c | 71 | 1.655 (1.616) | 0.039 | −6.0 |
| B4 | ″ | 2d | 182 | 1.689 (1.647) | 0.042 | 2.0 |
| C1 | 1c | 2a | 64 | 1.648 (1.620) | 0.028 | −38.7^{c} |
| C2 | ″ | 2b | 52 | 1.683 (1.626) | 0.057 | 11.1 |
| C3 | ″ | 2c | 209 | 1.654 (1.620) | 0.034 | −10.3 |
| C4 | ″ | 2d | 473 | 1.676 (1.646) | 0.030 | 2.9 |

^{a}Determined by rotational rheometry,
^{b}Refractive index is represented by Fraunhofer D line (589 nm)
^{c}Determined by DSC.

In order to examine the photopolymerization kinetics, resin mixtures with stoichiometric thiol and alkyne (Yne:SH=1:2) groups were formulated from the synthesized thiol and yne monomers (Table 7). All formulations formed miscible resin mixtures with low viscosities (>473 cP), and the conversions were monitored using real-time Fourier Transform Infrared (FTIR) spectroscopy. Upon irradiation at 405 nm with an intensity of 30 mW/cm², both the thiol and alkyne groups reacted quickly as indicated by the disappearance of the corresponding thiol (2570 cm⁻¹) and alkyne (2120 cm⁻¹) peaks. However, the reactivity of the thiol and alkyne were found to vary significantly with the steric and electronic nature of the monomers and also with resin viscosities to have a dramatic influence on the polymerization kinetics. For example, in formulations A1-A4, the monomer 1a containing only 1° thiol showed varying reactivities across the alkyne monomers 2a-2d, indicative of the influence of viscosity and steric effects.

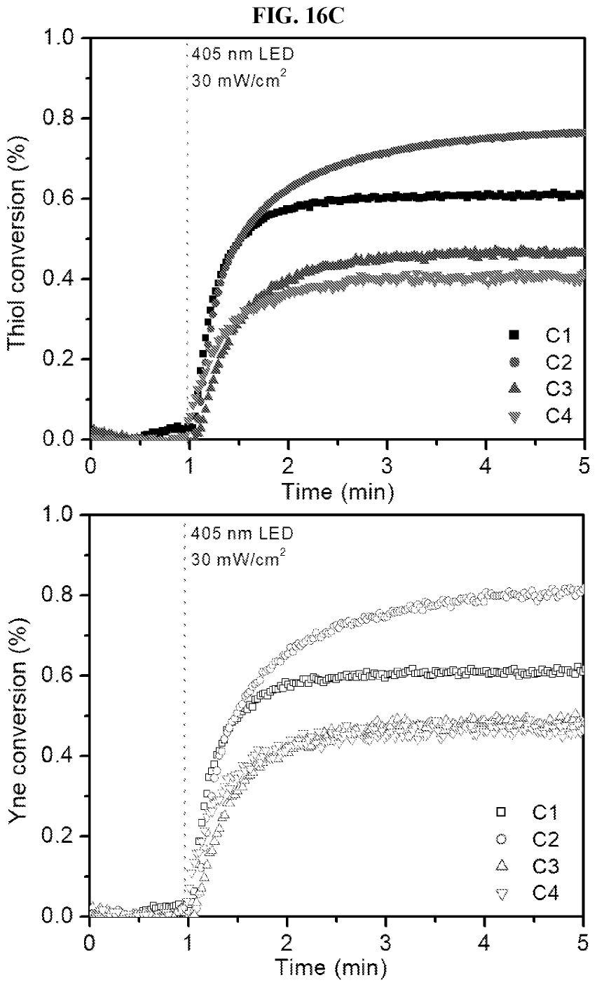

Interestingly, the thiol and alkyne conversions for highly flexible diyne monomer 2b and the monoyne 2a reached up to 80% in 5 min as compared to the rest of the diyne monomers 2c and 2d for which the conversions reached only ˜70% (FIG. 16A). This significant difference in polymerization kinetics of 2b is presumably due to the sterically less hindered back bone and its ability to form low viscosity resin mixtures. However, the effect of secondary interactions such as π-π stacking in diyne monomers 2a, 2c, 2d containing aryl groups cannot be ruled out. While all the formulations containing 2b showed high conversions of thiol as well as yne (˜80%), the conversions were found to be significantly lower for all the rest of the formulations containing yne monomers with aryl groups. This significant difference in conversions shows, without being bound by theory, the effects of steric hindrance and resin viscosities which upon network formation restrict the movement and hinder the accessibility of the thiol to react with the alkynes (FIGS. 16A-16C).

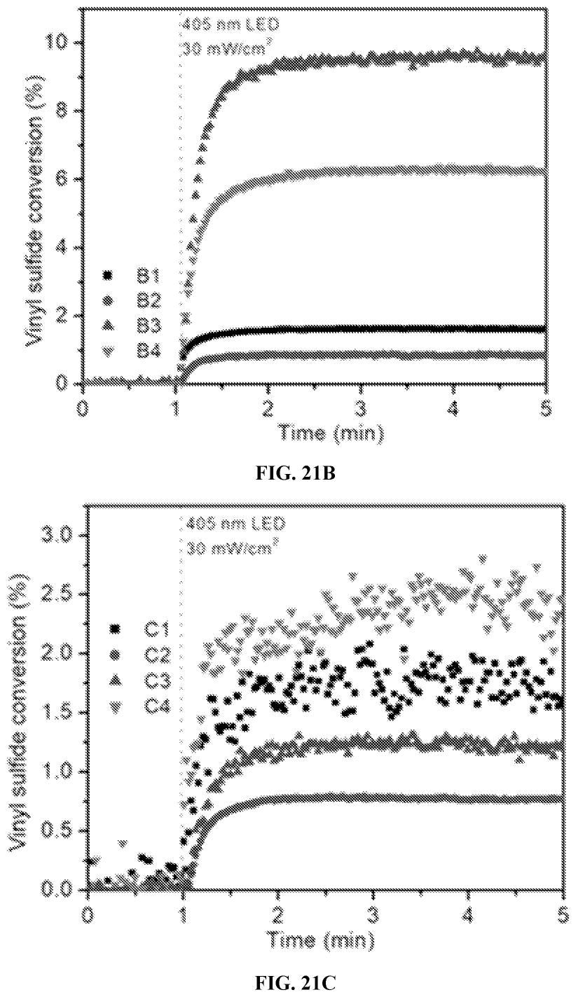

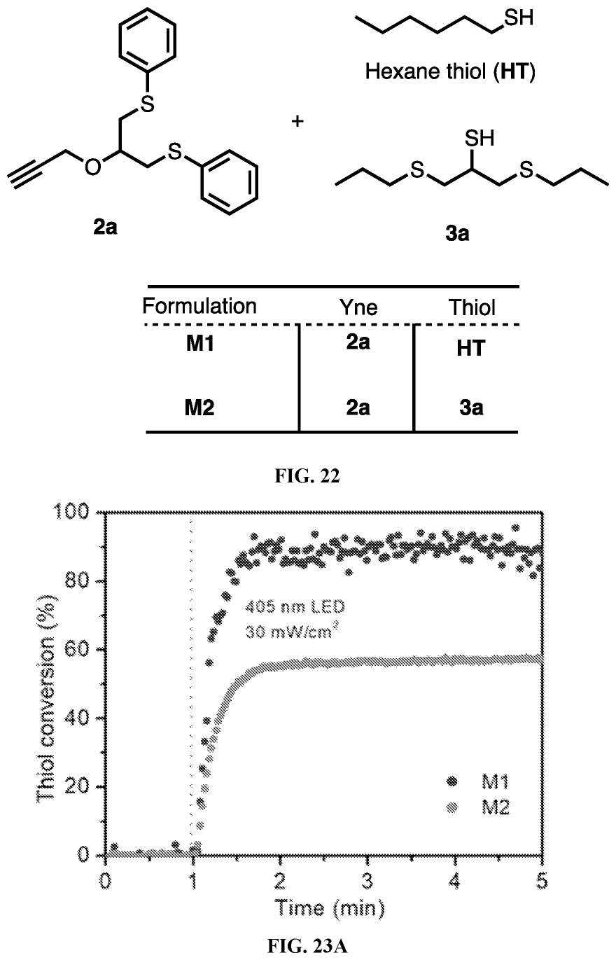

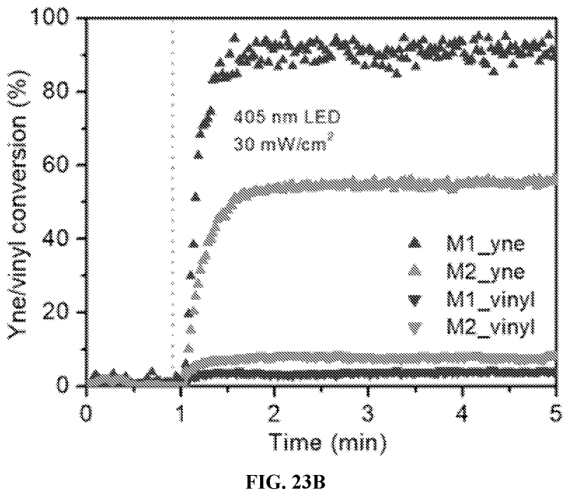

Moreover, in formulations containing 1a, the higher concentration of vinyl sulfide in A3 and A4 compared to that of A1 and A2 clearly shows the inability of the thiols to react even with vinylsulfide which is often several times more reactive than the corresponding alkynes (FIG. 21A). This inactivity of the vinyl sulfide in the system could be attributed to the steric hindrance induced after the reaction of one thiol. The reactivity of multifunctional thiols is highly influenced by the nature (i.e., 1° or 2°) and the relative position of the thiols. As expected the conversions were reduced to <80% for the formulations of 2b with monomer 1b and 1c containing 2° thiols. As seen in the kinetic rate plots the other yne monomers 2a, 2c and 2d containing bulky core structures reached a conversion of 60% or less in all cases (FIGS. 16B-16C). This discrepancy was reasoned to be due to the restricted mobility and potentially lower reactivity of the shorter 2° thiol groups which is difficult to access once the primary thiols of the same monomer have reacted. As pointed out previously, the increased steric hindrance of the 2° thiol increases the activation energy of the chain transfer step, resulting in a significantly reduced reaction rate. Though under lower initiation conditions, a similar trend in the reactivity of 1°, 2° and 3° thiols was observed in thiol-ene photopolymer systems due to steric factors.¹⁴ In order to better understand the reactivity of 2° thiols towards the alkynes, a model 2° thiol was synthesized following the general synthetic protocol described herein (FIG. 22). The reactivity difference of the alkyne towards 1° and 2° thiols was analyzed using hexanethiol (HT) and 3a as model 1° and 2° thiols, respectively. The real time FT-IR kinetics for formulations M1 and M2 containing stoichiometric 3a and HT with 2a (i.e., SH:Yne=2:1) clearly show that the reaction rate of the 2° thiol is slower than that of the 1° thiol (FIGS. 23A-23B). Since the 2° thiol shares most of structural similarities with 1b and 1c, the lower conversion of the model 2° thiol clearly demonstrates that the steric bulk and the position has significant influence in the thiol-yne reactivity.

Also, in some cases the functional group conversion at a given time was found to be slightly higher for the alkyne than the thiol. This behavior is reflective of the reaction of the vinyl sulfide that was formed by the initial thiol-yne reaction and is consistent with earlier observations that the addition of thiol to alkyne leads to formation of the vinyl sulfide is significantly slower than the reaction between the thiol and vinyl sulfide. This difference may be also attributed to consumption of alkyne or vinyl sulfide functional groups by chain-growth addition mechanisms, i.e., homo- or copolymerization. Photopolymerizations were also performed at an elevated temperature 60° C. and at off-stoichiometric conditions (Yne:SH=1:3). Though a slight improvement in yne conversion was observed under off-stoichiometric conditions, no significant change in the conversion was observed at the elevated temperatures indicating that the resin viscosity has little effect on the conversion and confirming the inability of the 2° thiol to participate efficiently in the reaction, even at elevated temperatures.

### Example 6: Thermomechanical Properties of High n Thiol-Yne Photopolymers

One of the key feature of the thiol-yne reaction over the analogous thiol-ene click reaction is that one alkyne reacts with two thiol moieties to give polymers with higher cross-link density than the corresponding thiol-ene formulations. As mentioned above, all formulations formed completely miscible resin mixtures with low viscosities (>473 cP) and formed optically transparent films between the glass slides upon irradiating with 405 nm light at 30 mW/cm². Though the conversions were low particularly for the resins formulations containing diynes 2c and 2d with multi-thiols 1b and 1c, all those were well above the gel point conversions and formed mechanically robust films. Moreover, as pointed out previously stoichiometrically balanced, step-growth polymerization systems in which the rate of initial addition is slower than the subsequent addition (i.e., kP, 2/kP, 1>1) have a lower gel-point conversion than the Flory-Stockmayer prediction. One of the key features of the step growth thiol-ene and thiol-yne networks is their rather narrow glass transition region resulting from the uniform network formation.

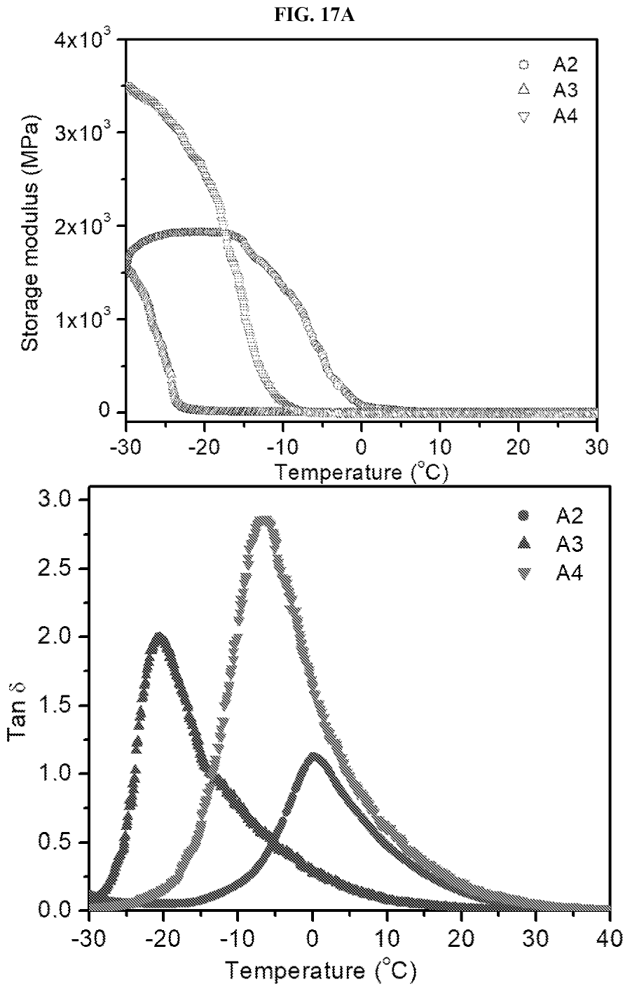

A similar trend was observed in thiol-yne networks formed here as well indicative of the relatively uniform network formation. However, the tan δ curves obtained for the network formed from dithiol and diyne formulations were found to be somewhat broader compared to previously reported dithiol-diyne networks (FIGS. 17A-17C). The reason for this discrepancy is believed to be the non-uniform network formation due to the presence of two different thiol functionalities with different chemical environments. A 11 the glass transition temperatures for the network polymers were measured by DMA except for formulations A1, B1 and C1 which were measured by DSC analysis due to the difficulty in large sample preparation. The glass transitions obtained for various thiol-yne formulations are listed in Table 7. As expected, the photopolymers obtained from formulations A2, B2 and C2 exhibited higher T_{g} values between 0° C. to 19° C. in accordance with the higher conversions. Whereas, formulations A1, B1 and C1 exhibited T_{g} below −30° C. due to the formation of mostly linear polymers with these formulations.

However, an increase in T_{g} values was observed for all the rest of formulations containing diynes 2c and 2d. As expected polymers A4, B4 and C4 bearing the rigid thiobenzenethiol (TBT) core displayed higher T_{g} values (−3.8 to 2.9° C.) compared to that of A3, B3 and C3 bearing an ethane dithiol (EDT) core with T_{g} values in the range of −18 to −6° C. Although the conversions of thiol and alkynes in these formulations were well above the gel point, the low overall conversions limit the expected crosslink density and T_{g} values. Thus, a broad range of thermomechanical properties were accessed for these photopolymer systems formed from diynes and multifunctional thiols with T_{g} values ranging from −18 to 19° C. Such high refractive index, low T_{g} materials are well suited for applications in optics and ophthalmic implants. Moreover, each sample exhibits a similar transition from a glassy regime, where the elastic modulus is greater than 1 GPa, to a rubbery regime with significantly lower modulus.

### Example 7: Refractive Index of Thiol-Yne Photopolymers

As a result of the high inherent atomic refraction, sulfur containing polymers are expected to exhibit high refractive indices. Therefore, the increase in refractive index of the photopolymers formed from thiol-x polymerizations is a direct result of the incorporation of sulfide moieties in the network. One important feature of thiol-yne photopolymerization is that it allows the introduction of a large number of sulfide linkages in comparison to that of the corresponding thiol-ene formulation. This feature of the thiol-yne reaction is attributed to the ability of one alkyne to react with two thiol groups which is not possible for thiol-ene systems and results in the increased number of sulfurs in the system. Using this approach, photopolymers with large changes in refractive index were readily achieved by simply switching the monomer functionality from the vinyl to the corresponding alkyne reactive group.

As can be seen from Table 7, each combination of synthesized thiol and yne monomers resulted in photopolymers with refractive indices n_{D}(2° C.) spanning a 0.04 range from approximately 1.65 to 1.69. These RI values at low conversions (˜60%) are already higher than those reported earlier for analogous thiol-ene systems. The high refractive index values displayed by these network polymers are the direct result of the monomer core design incorporating substituents with high molar refraction. Thus, the aromatic dithiol core in 2d significantly increases the refractive index by 0.03 compared to the alkyl counterpart 2c. Using excess thiol i.e., the off-stoichiometry in the resin formulation may improve the polymer refractive index as well as the conversion of the limiting reagent (i.e., yne monomer) by reducing the diffusional restrictions. However, an attempt to improve the polymer refractive index by off-stoichiometric combination of 1b and 1c across 2d (thiol-yne, 3:1) impacted negatively reducing the refractive index by 0.02.

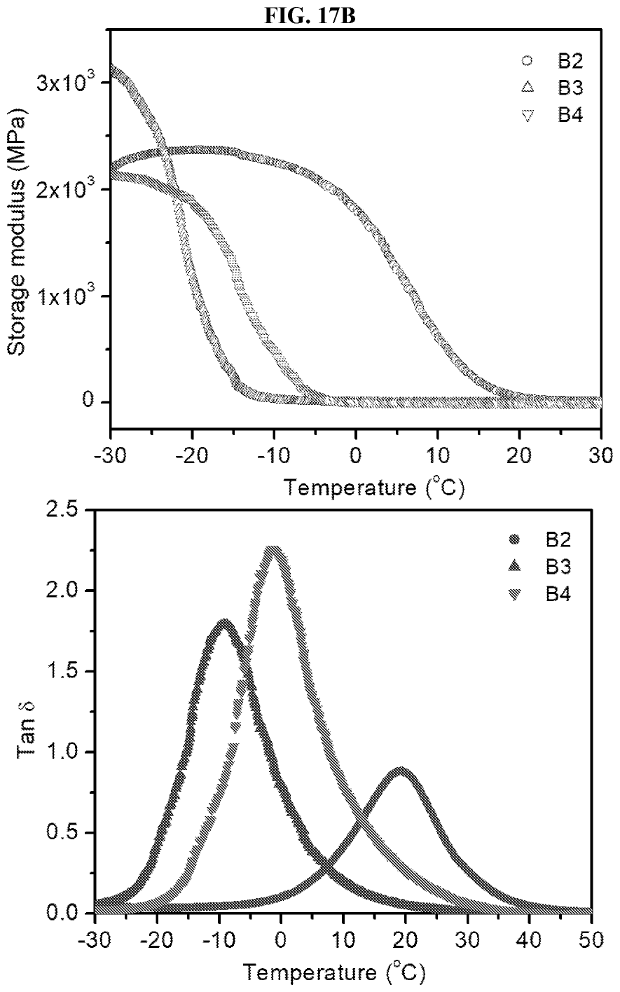

A plausible explanation for this discrepancy is that the free thiols contribute less to improve the refractive index in comparison to the thioether moieties resulting from the thiol-yne click reactions. This behavior is evident from the dramatic change in the refractive index (0.08) observed for formulation B2 (dithiol 1b and yne monomer 2b) during polymerization. Upon exposure to 405 nm light at 30 mW/cm² intensity, the refractive index of the resin changed from 1.60 to 1.68 in 5 min indicative of the large number of thioether linkages formed due to high conversion. Since there are no aryl groups present in this resin system, the concentration of sulfide linkages gives the direct measure of the polymer refractive index. Interestingly, the measured polymer refractive index showed a linear relationship with the thiol conversion as shown in FIG. 18.

### Example 8: Applications of High RI Thiol-Yne Monomers in Two Stage Photopolymer System

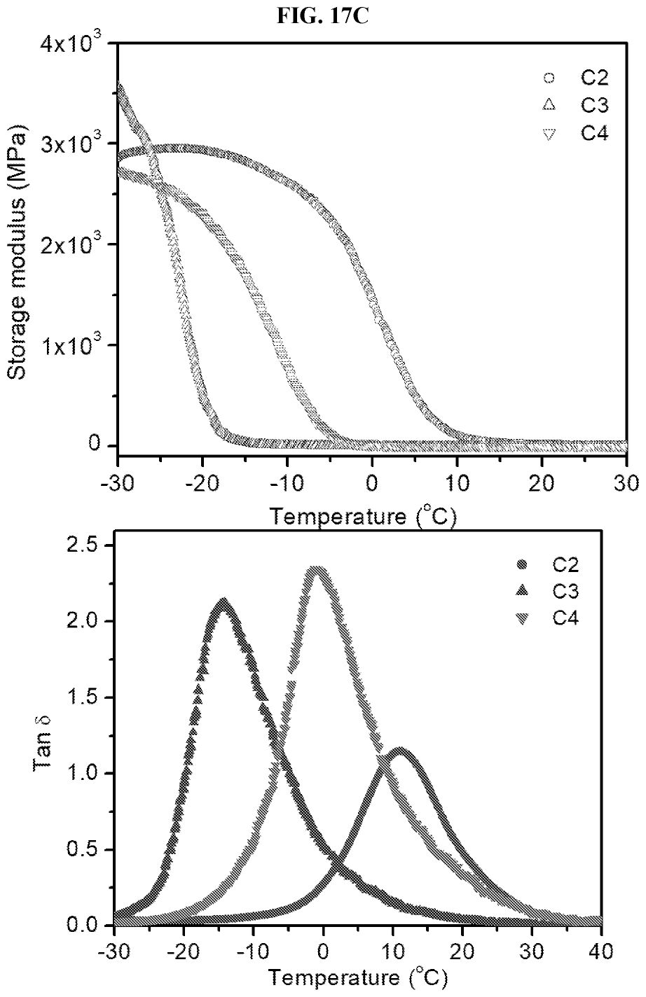

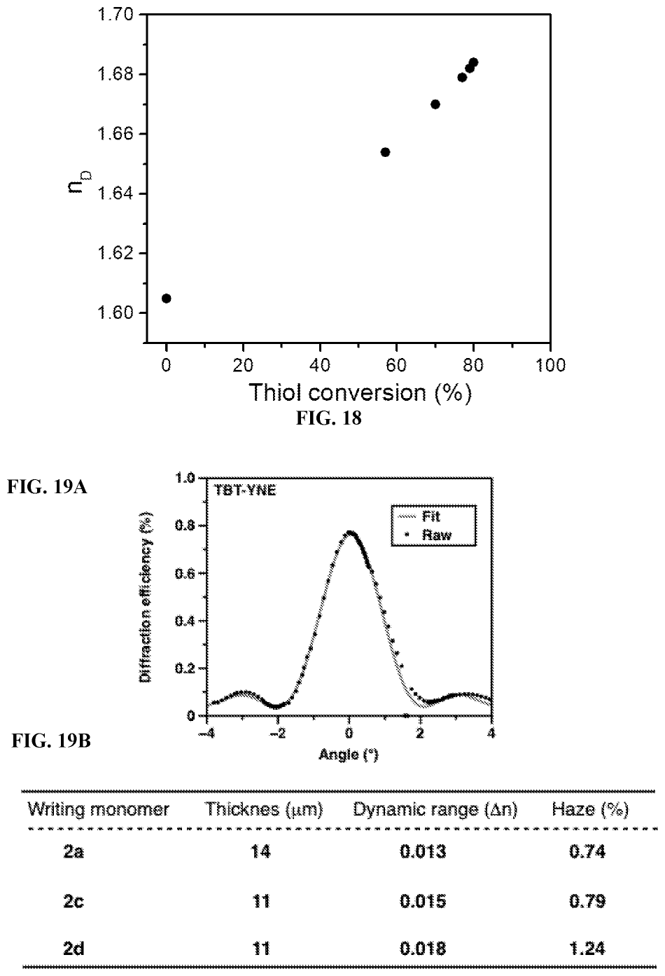

The ability of a photopolymer system to achieve high index contrast between the matrix and the writing monomers upon photo exposure is one of the key specifications for novel holographic material development. However, achieving such a high index contrast is often challenging due to limited availability of proper high RI monomers with low viscosities. To this end, a thiol-ene writing chemistry was recently devised and implemented for high fidelity hologram recording via a linear polyurethane binder approach. Following a similar approach, these synthesized high RI alkyne monomers were used to record holograms with relatively high Δn in thin films. As seen from FIG. 18, a peak diffraction efficiency of 80% was achieved in high spatial frequency when 2d and commercially available trimethylolpropane tris(3-mercaptopropionate (TMPTMP) were used as the writing monomers. The angular playback spectrum of the recorded hologram showed good agreement with a fit to coupled-wave theory. Dynamic ranges (Δn) and thickness of holograms using the other alkyne writing monomers 2a and 2c are also summarized in FIGS. 19A-19B. The hologram recorded with 2d exhibits the highest Δn of 0.018 presumably due to the higher refractive index of this writing monomer formulation as compared to 2a and 2c. However, the diffusional blurring induced by the incomplete conversion of these writing monomers reduced the overall index contrast and remains a limitation in achieving high index modulation. Interestingly the haze value measured of all these holograms was found to be lower than 1.5%. A slightly higher haze observed for monomer 2d is attributed to the low miscibility of this rigid core monomer with the urethane binder implemented here.

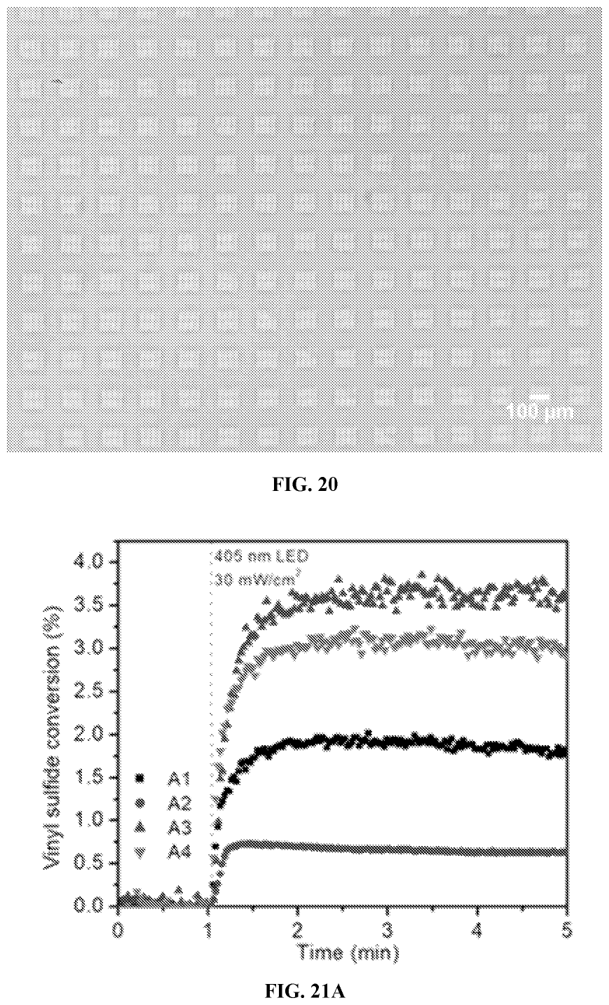

Another application of high refractive index photocurable thiol-yne resins is demonstrated by recording two-dimensional, micrometer scale high fidelity refractive index structures on a poly(urethane-thiourethane) stage 1 matrix. The model system demonstrated here consisted of a poly(urethane-thiourethane) matrix with high refractive index B2 resin incorporated. The first stage poly(urethane-hiourethane) matrix was cured at ambient temperature and was casted as a 250-μm-thick film of this material between two glass slides. In the second stage, the film was irradiated using a 405 nm LED source through a photomask to record a two-dimensional array of refractive index structures (100 m squares), as shown by the optical microscope image in FIG. 20.

### Enumerated Embodiments

The following exemplary embodiments are provided, the numbering of which is not to be construed as designating levels of importance:

Embodiment 1 provides a composition comprising:
at least one polymer;
a polymer binder comprising a plurality of allyl groups; and
at least one monomer of formula (I):

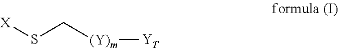

and at least one monomer of formula (II):

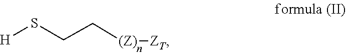

wherein:
each occurrence of X is independently H or optionally substituted C₆₋₁₄ aryl;
each Y is independently —S—, —CH₂—, —CH₂CH₂—, —CH(CH₃)CH₂—, —CH₂CH(CH₃)—, —CH(SH)—, —CH[O—CH₂—CH═CH₂]—, or —CH[O—CH₂—C≡CH]—;
each Y_{T} is independently H, —SH, —CH═CH₂, —C≡CH, or optionally substituted C₆₋₁₄ aryl;
each Z is independently —S—, —CH₂, —CH₂CH₂—, —CH(CH₃)CH₂—, —CH₂CH(CH₃)—, or —CH(SH)—;
each Z_{T} is independently H, —SH or —CH₂SH;
m is an integer ranging from 0 to 100; and
n is an integer ranging from 0 to 100.

Embodiment 2 provides the composition of embodiment 1, wherein the polymer is a linear polyurethane.

Embodiment 3 provides the composition of any one of embodiments 1-2, wherein the polymer binder comprises from about 0 to 80 mol % allyl groups.

Embodiment 4 provides the composition of any one of embodiments 1-3, wherein the polymer comprises a polycaprolactone-block-polytetrahydrofuran-block-polycaprolactone.

Embodiment 5 provides the composition of any one of embodiments 1-4, wherein the ratio of the monomer of formula (I) to the monomer of formula (II) is about 9:1 to about 1:9.

Embodiment 6 provides the composition of any one of embodiments 1-5, wherein (Z)ₙ—Z_{T} comprises at least one —SH moiety.

Embodiment 7 provides the composition of any one of embodiments 1-6, wherein (Z)ₙ—Z_{T} comprises at least two —SH moieties.

Embodiment 8 provides the composition of any one of embodiments 1-7, wherein the monomer of formula (II) is selected from the group consisting of:

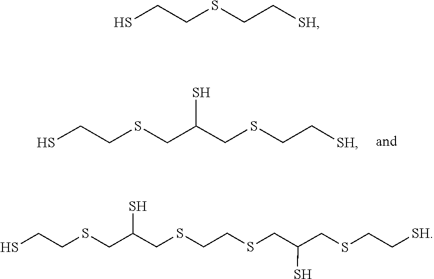 [SMILES: SCCSCCS ; SCCSCC(S)CSCCS ; SCCSCC(S)CSCCSCC(S)CSCCS]

Embodiment 9 provides the composition of any one of embodiments 1-8, wherein X is phenyl.

Embodiment 10 provides the composition of any one of embodiments 1-9, wherein (Y)ₘ is a linear chain.

Embodiment 11 provides the composition of any one of embodiments 1-10, wherein (Y)ₘ comprises at least one of —CH(O—CH₂—CH═CH₂)— or —CH(O—CH₂—C≡CH)—.

Embodiment 12 provides the composition of any one of embodiments 1-11, wherein (Y)ₘ comprises at least two moieties independently selected from —CH(O—CH₂—CH═CH₂)— and —CH(O—CH₂—C≡CH)—.

Embodiment 13 provides the composition of any one of embodiments 1-12, wherein the monomer of formula (I) is selected from the group consisting of:

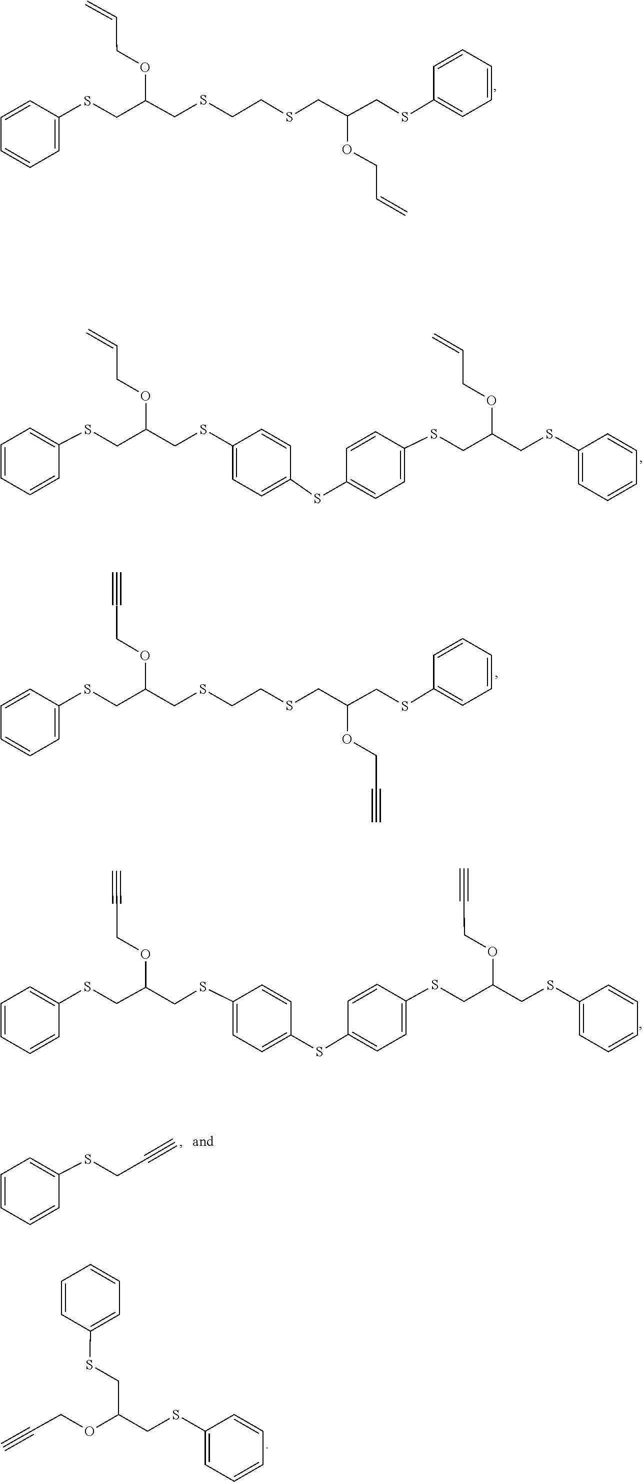

Embodiment 14 provides the composition of any one of embodiments 1-13, wherein the monomer of formula (I) and the monomer of formula (II) in total comprise about 1 to 80% (w/w) of the composition.

Embodiment 15 provides a polymerized composition of any one of embodiments 1-14.

Embodiment 16 provides a polymerized composition of any one of embodiments 1-15, wherein the plurality of allyl groups and the monomers of formula (I) and formula (II) are cross-linked.

Embodiment 17 provides a film comprising the composition of any one of embodiments 1-14.

Embodiment 18 provides a method of recording a hologram, the method comprising: providing the composition of any one of embodiments 1-14; and exposing the composition to laser irradiation to form a hologram.

Embodiment 19 provides method of embodiment 18, wherein the providing step comprises coating an inert substrate with the film.

Embodiment 20 provides method of any one of embodiments 18-19, wherein the exposing step comprises cross-linking the polymer binder and the monomers of formula (I) and formula (II).

Embodiment 21 provides method of any one of embodiments 18-20, wherein the hologram has an index modulation (Δn) of about 0.01 to about 0.06.

Embodiment 22 provides a composition comprising:
at least one monomer of formula (I-A):

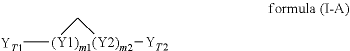

and at least one monomer of formula (II):

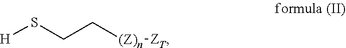

wherein:
each occurrence of X is independently H or optionally substituted C₆₋₁₄ aryl;
each occurrence of Y1 and Y2 is independently —S—, —CH₂—, —CH₂CH₂—, —CH(CH₃)CH₂—, —CH₂CH(CH₃)—, —CH(SH)—, —CH[O—CH₂—CH═CH₂]—, or —CH[O—CH₂—C≡CH]—;
each occurrence of Y_{T1} and Y_{T2} is independently H, —SH, —CH═CH₂, —C≡CH, or optionally substituted C₆₋₁₄ aryl;
each Z is independently —S—, —CH₂, —CH₂CH₂—, —CH(CH₃)CH₂—, —CH₂CH(CH₃)—, or —CH(SH)—;
each Z_{T} is independently H, —SH or —CH₂SH;
each m1 and m2 is independently an integer ranging from 0 to 100; and
n is an integer ranging from 0 to 100.

Embodiment 23 provides a polymerized composition of embodiment 22.

Embodiment 24 provides the polymerized composition of embodiment 23, having a refractive index of about 1.63 to about 1.69.

Embodiment 25 provides the composition of any one of embodiments 22-24, wherein (Z)ₙ—Z_{T} comprises at least one —SH moiety.

Embodiment 26 provides the composition of any one of embodiments 22-25, wherein (Z)ₙ—Z_{T} comprises at least two —SH moieties.

Embodiment 27 provides the composition of any one of embodiments 22-26, wherein the monomer of formula (II) is selected from the group consisting of:

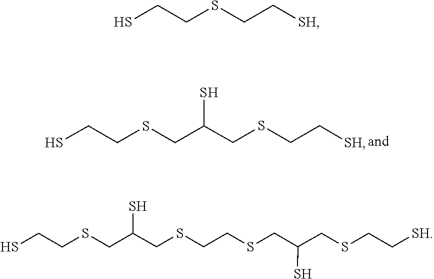 [SMILES: SCCSCCS ; SCCSCC(S)CSCCS ; SCCSCC(S)CSCCSCC(S)CSCCS]

Embodiment 28 provides the composition of any one of embodiments 22-27, wherein m1 is 1, Y1 is —S—, and YT₁ is phenyl.

Embodiment 29 provides the composition of any one of embodiments 22-28, wherein at least one of (Y1)ₘ₁ and (Y2)ₘ₂ is a linear chain.

Embodiment 30 provides the composition of any one of embodiments 28, wherein at least one of (Y1)ₘ₁ and (Y2)ₘ₂ comprises at least one of —CH(O—CH₂—CH═CH₂)— or —CH(O—CH₂—C≡CH)—.

Embodiment 31 provides the composition of any one of embodiments 30, wherein at least one of (Y1)ₘ₁ and (Y2)ₘ₂ comprises at least two moieties independently selected from —CH(O—CH₂—CH═CH₂)— and —CH(O—CH₂—C≡CH)—.

Embodiment 32 provides the composition of any one of embodiments 22-31, wherein Y_{T1} and Y_{T2} are —C≡CH.

Embodiment 33 provides the composition of any one of embodiments 22-32, wherein the monomer of formula (I-A) is selected from the group consisting of:

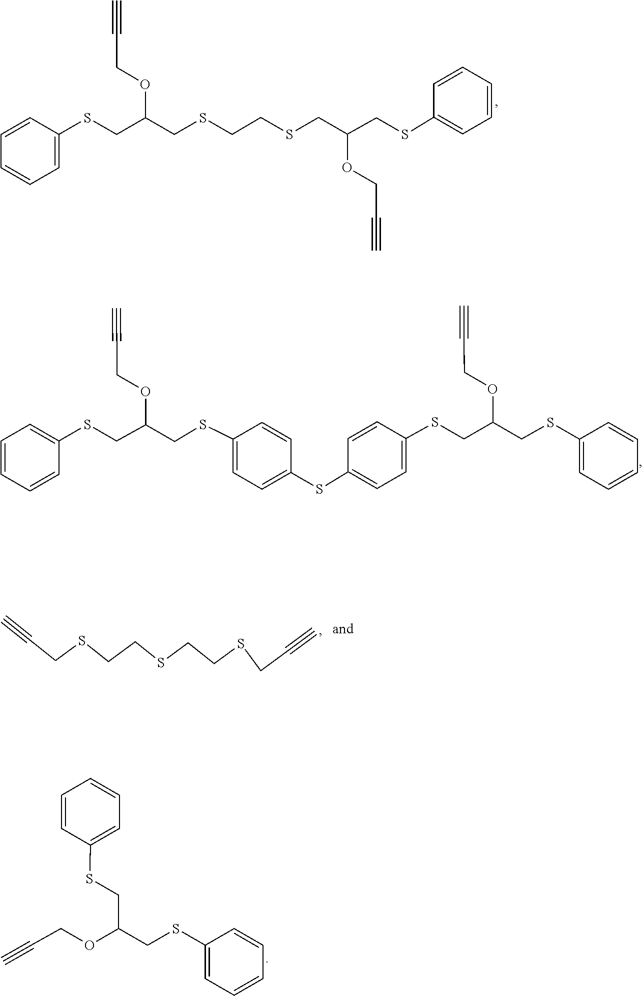 [SMILES: C#CCOC(CSCCSCC(CSc1ccccc1)OCC#C)CSc1ccccc1 ; C#CCOC(CSc1ccccc1)CSc1ccc(Sc2ccc(SCC(CSc3ccccc3)OCC#C)cc2)cc1 ; C#CCSCCSCCSCC#C ; C#CCOC(CSc1ccccc1)CSc1ccccc1]

1. A composition comprising:
at least one polymer;
a polymer binder comprising a plurality of allyl groups; and
at least one monomer of formula (I): 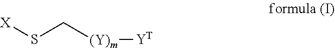
and at least one monomer of formula (II): 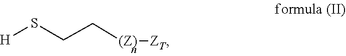
wherein:
each occurrence of X is independently H or optionally substituted C₆₋₁₄ aryl;
each Y is independently —S—, —CH₂—, —CH₂CH₂—, —CH(CH₃)CH₂—, —CH₂CH(CH₃)—, —CH(SH)—, —CH[O—CH₂—CH═CH₂]—, or —CH[O—CH₂—C≡CH]—;
each Y_{T} is independently H, —SH, —CH═CH₂, —C≡CH, or optionally substituted C₆₋₁₄ aryl;
each Z is independently —S—, —CH₂, —CH₂CH₂—, —CH(CH₃)CH₂—, —CH₂CH(CH₃)—, or —CH(SH)—;
each Z_{T} is independently H, —SH or —CH₂SH;
m is an integer ranging from 0 to 100; and
n is an integer ranging from 0 to 100.

2. The composition of claim 1, wherein at least one of the following applies:
i) the polymer is a linear polyurethane,
ii) the polymer binder comprises from about 0 to 80 mol % allyl groups; and
iii) the polymer comprises a polycaprolactone-block-polytetrahydrofuran-block-polycaprolactone.

3. (canceled)

4. (canceled)

5. The composition of claim 1, wherein the ratio of the monomer of formula (I) to the monomer of formula (II) is about 9:1 to about 1:9.

6. The composition of claim 1, wherein (Z)ₙ—Z_{T} comprises at least one —SH moiety.

7. The composition of claim 1, wherein (Z)ₙ—Z_{T} comprises at least two —SH moieties.

8. The composition of claim 1, wherein the monomer of formula (II) is selected from the group consisting of:

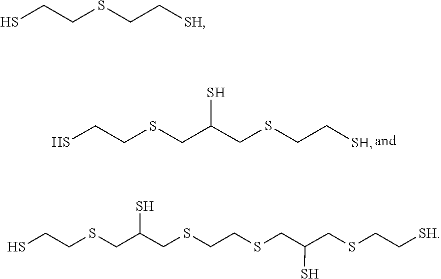 [SMILES: SCCSCCS ; SCCSCC(S)CSCCS ; SCCSCC(S)CSCCSCC(S)CSCCS]

9. The composition of claim 1, wherein at least one of the following applies:
i) X is phenyl;
ii) (Y)ₘ is a linear chain; and
iii) (Y)ₘ comprises at least one of —CH(O—CH₂—CH═CH₂)— or —CH(O—CH₂—C≡CH)—.

10. (canceled)

11. (canceled)

12. (canceled)

13. The composition of claim 1, wherein the monomer of formula (I) is selected from the group consisting of:

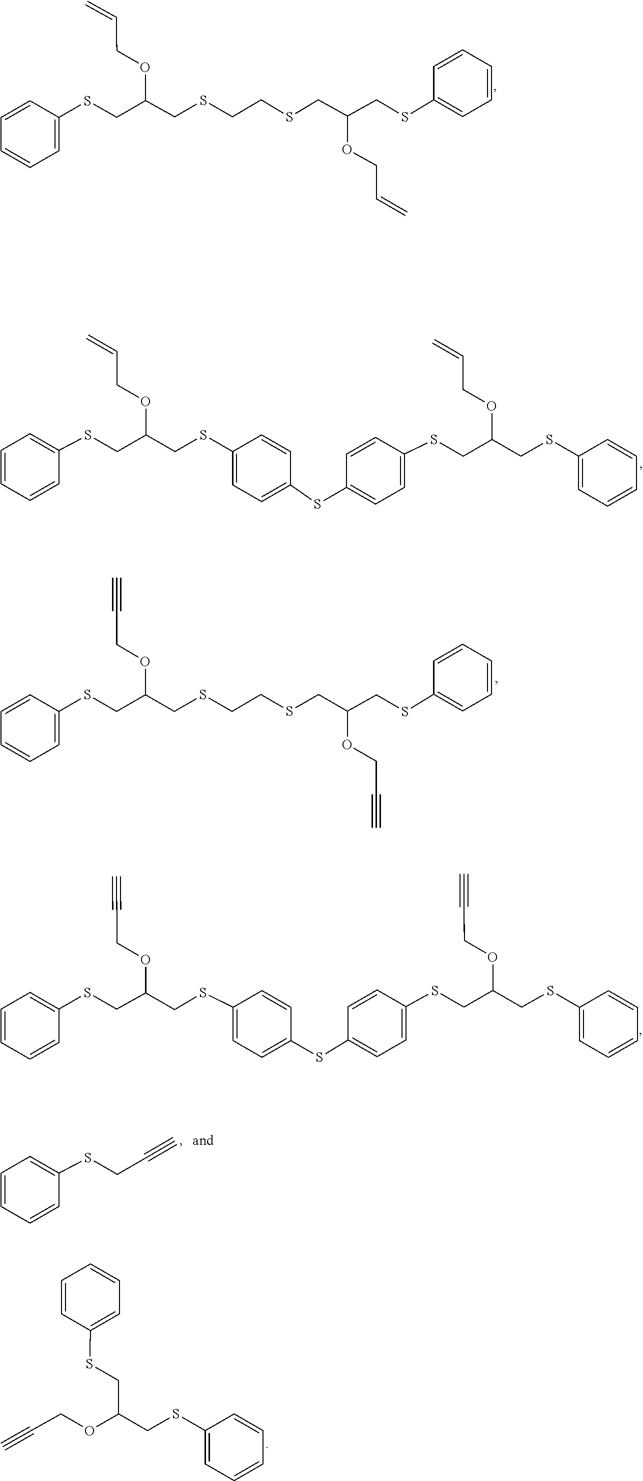

14. The composition of claim 1, wherein the monomer of formula (I) and the monomer of formula (II) in total comprise about 1 to 80% (w/w) of the composition.

15. (canceled)

16. The composition of claim 1, which is polymerized, optionally wherein the plurality of allyl groups in the polymer binder and the monomers of formula (I) and formula (II) are cross-linked.

17. (canceled)

18. A method of recording a hologram, the method comprising:
providing a film comprising the composition of claim 1; and
exposing the film to laser irradiation to form a hologram.

19. The method of claim 18, wherein the providing step comprises coating an inert substrate with the film.

20. The method of claim 18, wherein the exposing step comprises cross-linking the polymer binder and the monomers of formula (I) and formula (II).

21. The method of claim 18, wherein the hologram has an index modulation (Δn) of about 0.01 to about 0.06.

22. A composition comprising:
at least one monomer of formula (I-A): 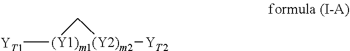
and at least one monomer of formula (II): 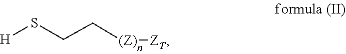
wherein:
each occurrence of X is independently H or optionally substituted C₆₋₁₄ aryl;
each occurrence of Y1 and Y2 is independently —S—, —CH₂—, —CH₂CH₂—, —CH(CH₃)CH₂—, —CH₂CH(CH₃)—, —CH(SH)—, —CH[O—CH₂—CH═CH₂]—, or —CH[O—CH₂—C≡CH]—;
each occurrence of Y_{T1} and Y_{T2} is independently H, —SH, —CH═CH₂, —C≡CH, or optionally substituted C₆₋₁₄ aryl;
each Z is independently —S—, —CH₂, —CH₂CH₂—, —CH(CH₃)CH₂—, —CH₂CH(CH₃)—, or —CH(SH)—;
each Z_{T} is independently H, —SH or —CH₂SH;
each m1 and m2 is independently an integer ranging from 0 to 100; and
n is an integer ranging from 0 to 100.

23. (canceled)

24. The composition of claim 22, which is polymerized, optionally having a refractive index of about 1.63 to about 1.69.

25. The composition of claim 22, wherein (Z)ₙ—Z_{T} comprises at least one —SH moiety.

26. (canceled)

27. The composition of claim 22, wherein the monomer of formula (II) is selected from the group consisting of:

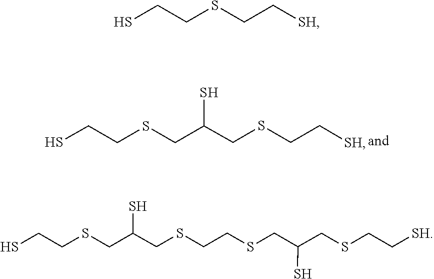 [SMILES: SCCSCCS ; SCCSCC(S)CSCCS ; SCCSCC(S)CSCCSCC(S)CSCCS]

28. The composition of claim 22, wherein at least one of the following applies:
i) m1 is 1, Y1 is —S—, and YT₁ is phenyl,
ii) at least one of (Y1)ₘ₁ and (Y2)ₘ₂ is a linear chain:
iii) at least one of (Y1)ₘ₁ and (Y2)ₘ₂ comprises at least one of —CH(O—CH₂—CH═CH₂)— or —CH(O—CH₂—C≡CH)—; and
iv) Y_{T1} and Y_{T2} are —C≡CH.

29. (canceled)

30. (canceled)

31. (canceled)

32. (canceled)

33. The composition of claim 22, wherein the monomer of formula (I-A) is selected from the group consisting of: 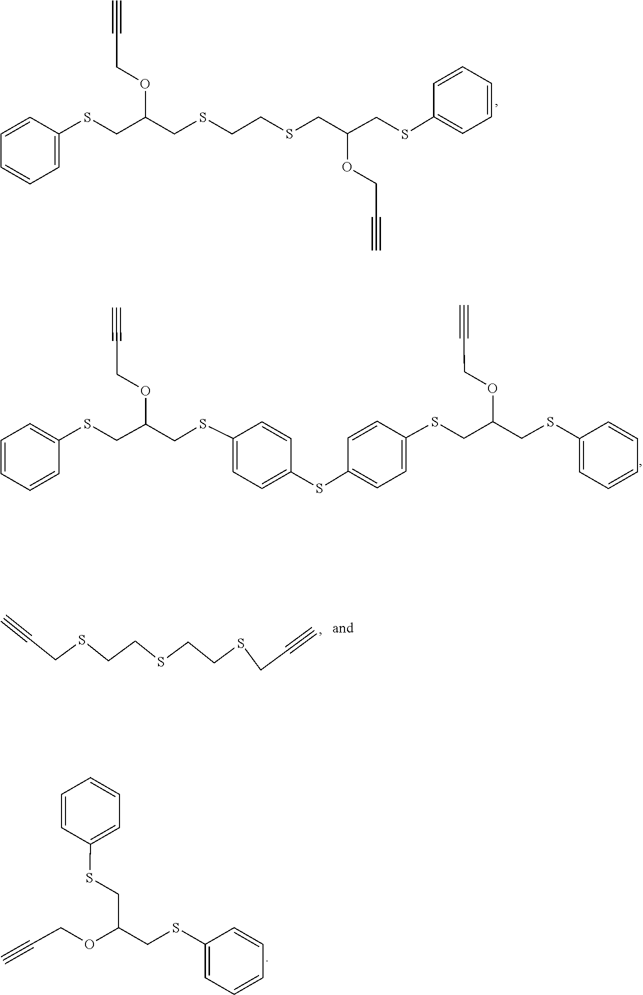 [SMILES: C#CCOC(CSCCSCC(CSc1ccccc1)OCC#C)CSc1ccccc1 ; C#CCOC(CSc1ccccc1)CSc1ccc(Sc2ccc(SCC(CSc3ccccc3)OCC#C)cc2)cc1 ; C#CCSCCSCCSCC#C ; C#CCOC(CSc1ccccc1)CSc1ccccc1]
